(19) United States
(12) Patent Application Publication
(10) Pub. No.: US 2025/0366363 A1
(43) Pub. Date: Nov. 27, 2025

(54) PEROVSKITE LAYER, METHOD OF PREPARING THE SAME AND PHOTOELECTRIC DEVICE

(71) Applicant: The Hong Kong University of Science and Technology, Hong Kong (CN)

(72) Inventor: Yuanyuan ZHOU, Hong Kong (CN)

(21) Appl. No.: 19/212,857

(22) Filed: May 20, 2025

Related U.S. Application Data
(60) Provisional application No. 63/651,408, filed on May 24, 2024.

(51) Int. Cl. H10K 85/50; H10K 30/10; H10K 30/50

(52) U.S. Cl. CPC H10K 85/50; H10K 30/10; H10K 30/50

(57) ABSTRACT

A perovskite layer comprising a perovskite compound and a surfactant, wherein the perovskite compound is represented by Formula 1: (A⁺)_{1-y}(A′⁺)_{y}(M²⁺)(X⁻)₃, wherein y is 0.01-0.99; M²⁺ is Pb²⁺, Sn²⁺, or Ge²⁺; each of A⁺ and A′⁺ is independently Cs⁺, Rb⁺, CH₃NH₃⁺, CH₃CH₂NH₃⁺, H(C═NH₂)NH₂⁺, or Me(C═NH₂)NH₂⁺; and X⁻ for each instance is independently F⁻, Cl⁻, Br⁻, or I⁻, wherein A⁺ and A′⁺ are the same or different; and the surfactant comprises a sulfonate surfactant, an alcohol alkoxylate surfactant, a quaternary ammonium surfactant, or mixtures thereof. The photoelectric device comprising the perovskite layer can achieve an improved power conversion efficiency (PCE) while can maintain the stability of PCE in devices.

### CROSS-REFERENCE TO RELATED APPLICATIONS

This application claims the benefit of priority of U.S. Provisional Application No. 63/651,408, filed on May 24, 2024, the contents of which being hereby incorporated by reference in their entirety for all purposes.

### TECHNICAL FIELD

The present disclosure relates to a perovskite layer, a method of preparing the same and a photoelectric device.

### BACKGROUND

Perovskite solar cells (PSCs) are recognized as one of the most promising future photovoltaic technologies in a wide range of application scenarios, including building-integrated photovoltaics, as it combines the merits of potentially low manufacturing costs and high-power conversion efficiencies (PCEs). The certified record PCE of PSCs has rapidly climbed in recent years, continuously injecting excitement into the photovoltaic industry. Nevertheless, there is still an outstanding concern on the long-term durability of PSCs in practical operating conditions with complex stressors of light, heat, and moisture, calling for an in-depth fundamental investigation on the relationships between microscopic structure and performance. There are numerous studies that have suggested that device heterointerface plays a dominating role in the long-term durability of PSCs. Attainment of ideal microstructural and functional integrity at device heterointerfaces is thus a key step to optimizing carrier injection and thermal management, to minimize moisture ingression, and to mitigate mechanical failure due to interfacial fatigue as well as accumulated thermal stress.

Studies of interfacial engineering have had a primary focus on chemical passivation on perovskite top and bottom (also referred to as “buried”) surfaces/interfaces, to lower the defect density, to manipulate energy level alignment, to enhance the phase purity, etc. However, insights into the microstructural integrity of these heterointerfaces are usually missing, which eventually dictates the functional properties. Especially, the perovskite heterointerfaces have been generally treated as an ideally continuous and flat microstructure type. In fact, perovskite thin films in state-of-the-art PSCs are invariably polycrystalline, consisting of a dense packing of individual grains.

However, current research on the surface microstructure of perovskite films, particularly on the microstructure of individual grain that constitutes the perovskite film, is not sufficiently thorough. Additionally, there is still a need to further improve the power conversion efficiency (PCE) and the stability of PCE in devices. The subject matters described herein address this unmet need.

### SUMMARY

The present disclosure provides strategies for improving the surfaces of perovskite materials so as to enhance their performance in photovoltaic devices.

In a first aspect, provided herein is a perovskite layer comprising a perovskite compound and a surfactant, wherein the perovskite compound is represented by Formula 1:

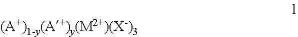

wherein y is 0.01-0.99;
M²⁺ is Pb²⁺, Sn²⁺, or Ge²⁺;
each of A⁺ and A′⁺ is independently Cs⁺, Rb⁺, CH₃NH₃⁺, CH₃CH₂NH₃⁺, H(C═NH₂)NH₂⁺, or Me(C═NH₂)NH₂⁺; and
X⁻ for each instance is independently F⁻, Cl⁻, Br⁻, or I⁻, wherein A⁺ and A′⁺ are the same or different; and
the surfactant comprises a sulfonate surfactant, an alcohol alkoxylate surfactant, a quaternary ammonium surfactant, or mixtures thereof.

In certain embodiments, the sulfonate surfactant comprises a sulfonic group substituted by a halogenated C₄-C₁₂ alkyl.

In certain embodiments, the quaternary ammonium surfactant comprises one or more C₁-C₁₆ alkyl substituents.

In certain embodiments, the surfactant comprises one or more of potassium tridecafluorohexane-1-sulfonate, sodium tridecafluorohexane-1-sulfonate, potassium nonafluorobutane-1-sulfonate, sodium nonafluorobutane-1-sulfonate, potassium henicosafluorodecane-1-sulfonate, sodium henicosafluorodecane-1-sulfonate, a poly(ethylene oxide)/poly(propylene oxide) (EO/PO) block copolymer, or N,N,N-trimethyloctan-1-aminium chloride.

In certain embodiments, M²⁺ is Pb²⁺; and each of A⁺ and A′⁺ is independently Cs⁺, CH₃NH₃⁺, or H(C═NH₂)NH₂⁺.

In certain embodiments, the perovskite layer comprises (H(C═NH₂)NH₂⁺)_{1-y}(Cs⁺)_{y}(Pb²⁺)(I⁻)₃, wherein y is 0.01-0.99.

In certain embodiments, the perovskite layer comprises a perovskite of Formula 2:

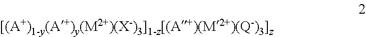

wherein y is 0.01-0.99;
z is 0.01-0.99;
M²⁺ is Pb²⁺, Sn²⁺, or Ge²⁺;
M′²⁺ is Pb²⁺, Sn²⁺, or Ge²⁺;
each of A⁺, A′⁺, and A″⁺ is independently Cs⁺, Rb⁺, CH₃NH₃⁺, CH₃CH₂NH₃⁺, H(C═NH₂)NH₂⁺, or Me(C═NH₂)NH₂⁺; and
X⁻ and Q⁻ for each instance is independently F⁻, Cl⁻, Br⁻, or I⁻, wherein A⁺ and A′⁺ are the same or different.

In certain embodiments, each of M²⁺ and M′²⁺ is Pb²⁺; each of A⁺ and A′⁺ is independently Cs⁺, CH₃NH₃⁺, or H(C═NH₂)NH₂⁺; and A″⁺ is CH₃NH₃⁺.

In certain embodiments, the perovskite layer comprises [(H(C═NH₂)NH₂⁺)_{1-y}(Cs⁺)_{y}(Pb²⁺)(I⁻)₃]_{1-z}[(CH₃NH₃⁺)(Pb²⁺)(Br⁻)₃]_{z}, wherein y is 0.01-0.99 and z is 0.01-0.99.

In certain embodiments, the perovskite layer comprises a plurality of perovskite grains, and a bottom surface of each of the plurality of perovskite grains comprises a single grain surface concave (GSC) and a convex ridge around the GSC, and wherein the average angle ξ of the perovskite grains between the line connecting the apex of the convex ridge to the center of the GSC and a top surface opposite to the bottom surface of the grain is 0°-1.5°.

In certain embodiments, the perovskite layer comprises a plurality of perovskite grains and a grain-boundary grooving (GBG) between the bottom surfaces of each of the adjacent perovskite grains, the GBG is surrounded by edges of the adjacent perovskite grains as a GBG sidewall, and wherein the average angle θ of the perovskite grains between the tangent to the GBG sidewall and a top surface opposite to the bottom surface of the grain is 0°-15°.

In a second aspect, provided herein is a method for producing the perovskite layer in the first aspect, wherein the method comprises:
providing a perovskite precursor solution comprising one or more metal salts each independently represented by the formula MX₂, two or more salts each independently represented by the formula AZ, the surfactant, and a solvent, wherein M is Pb²⁺, Sn²⁺, or Ge²⁺, A is Cs⁺, Rb⁺, CH₃NH₃⁺, CH₃CH₂NH₃⁺, H(C═NH₂)NH₂⁺, or Me(C═NH₂)NH₂⁺, X for each instance is independently F⁻, Cl⁻, Br⁻, or I⁻, and Z for each instance is independently F⁻, Cl⁻, Br⁻, or I⁻;
depositing the perovskite precursor solution on a surface of a charge transport layer (CTL) to form a wet film; and
annealing the wet film to form the perovskite layer.

In certain embodiments, wherein the perovskite precursor solution comprises (Cs⁺)(I⁻), (H(C═NH₂)NH₂⁺)(I⁻), (Pb²⁺)(I⁻)₂, and tridecafluorohexane-1-sulfonate.

In certain embodiments, wherein the perovskite precursor solution comprises (Cs⁺)(I⁻), (H(C═NH₂)NH₂⁺)(I⁻), (CH₃NH₃⁺)(Cl⁻), (Pb²⁺)(I⁻)₂, (CH₃NH₃⁺)(Pb²⁺)(Br⁻)₃, and tridecafluorohexane-1-sulfonate.

In certain embodiments, the surfactant has a concentration of 0.1-5 mg/ml in the perovskite precursor solution.

In certain embodiments, the one or more metal salts have a concentration of 0.5-2.0 M in the perovskite precursor solution.

In a third aspect, provided herein is a photoelectric device comprising the perovskite layer in the first aspect.

In certain embodiments, the photoelectric device is a perovskite solar cell (PSC), a perovskite light-emitting diode, a perovskite laser, or a perovskite photodetector.

In certain embodiments, the perovskite solar cell comprises an interfacial glue layer between the perovskite compound film and an adjacent charge transport layer.

In certain embodiments, the photoelectric conversion efficiency of the perovskite solar cell is 23.5-25.5%.

### BRIEF DESCRIPTION OF THE DRAWINGS

The foregoing aspects and many of the attendant advantages of this invention will become more readily appreciated and understood by reference to the following detailed description, when taken in conjunction with the accompanying drawing.

FIG. 1 depicts geometric characteristics and chemical tailoring of GSC microstructures at the perovskite grain-CTL micro-heterointerface. a, b, AFM topography of the perovskite film bottom surfaces with and without GSCs at the grain-CTL heterointerfaces, respectively. c-f, 2D AFM images (c, d) and 3D AFM images (e, f) of the selected regions (dashed lines) in perovskite film bottom surfaces with and without GSCs, respectively. g, h, 2D surface height line-profile (guided by dashed lines) on perovskite film bottom surfaces with (c) and without GSCs (d), respectively. i, Schematic illustration showing the topography of the surface of flipped perovskite grains at the heterointerface. The angles illustrated using dashed lines correspond to GBG angle θ and GSC angle ξ, respectively. j, Statistical distributions of GBG angle θ of perovskite films with GSCs (sample size, n=40) and without GSCs (n=40). k, Statistical distributions of GSC angle ξ of perovskite films with GSCs (sample size n=30) and without GSCs (sample size n=30). The box plot displays the mean, median line, upper minima and lower maxima, 25-75% box limits with 1.5× interquartile range whiskers.

FIG. 2 depicts microstructural evolution of GSCs at the perovskite grain-CTL micro-interface. a, Schematic illustration of microstructural evolution of GSCs. b, Schematic illustration of the role of potassium tridecafluorohexane-1-sulfonate (TFSAP) in tailoring GSCs. c, The determined surface free energy γₛ, GB energy γ_{gb} and the Δγ in the perovskite grains with and without GSCs. d, The normalized out-of-plane deformation ε_{z} in the perovskite grains with and without GSCs.

FIG. 3 depicts the optoelectronic, chemical, heat-transfer and thermomechanical properties of the perovskite grains-CTL micro-interface. a, Steady PL spectra of perovskite films with and without GSCs. b, Normalized TRPL spectra with biexponential fitting lines of perovskite films with and without GSCs. c, The current-voltage (I-V) curves with exponential fitting lines for the ohmic and trap-filled limited regions for the capacitor-like perovskite devices with the structure of ITO/SnO₂/perovskite/PCBM/Ag. d-e, Ultra-violet visible (UV-vis) absorption variations of perovskite films with and without GSCs under rigorous photothermal tests for 120 h (3-sun-intensity illumination; 80° C.), respectively. The inset is the optical photograph of degraded perovskite films after the test. f-g, The normalized transparent differential change in transmittance (dT/T) spectra at different pump delay times from 30 ns to 90 ns of perovskite samples with and without GSCs, respectively. h, The temperature distribution by FEA of the grain-CTL micro-interface with (top) and without GSCs (bottom). The scale bar is 100 nm. In this case of the internal thermal source, the temperature gradient is set from the top surface of the grain (85° C.) to the bottom surface of SnO₂ layer (20° C.). i, Schematic illustration of the delamination process for quantitively determining the mechanical reliability of the perovskite-CTL heterointerface. Standard perovskite grids are prefabricated on perovskite films by blade arrays and followed by a delamination process. The proportion of the delaminated area on the epoxy reflects the toughness level of the heterointerface. j, k, Optical photographs showing perovskite film residual areas on the CTL surface after the delamination process for the cases with and without GSCs, respectively. 1, Statistical distributions of the normalized delaminated area A_{d} of perovskite films with GSCs (pristine, sample size n=21; with I-SAM, sample size n=7) and without GSCs (pristine, sample size sample size n=22; with I-SAM, sample size n=9) after the delamination process. The box plot displays the mean, median line, upper minima and lower maxima, 25-75% box limits with 1.5× interquartile range whiskers. m, Statistical distribution of the scale (0B-5B) for rating the interfacial adhesion based on the normalized delamination area according to the ASTM D3359 standard. 0B represents that the removed area from substrate is greater than 65%, corresponding to the poorest interfacial strength. 1B, 2B, 3B, and 4B represent the 35-65%, 15-25%, 5-15% and less than 5% removed area, respectively. 5B represents no residual area on the substrate after delamination, corresponding to the strongest interfacial strength.

FIG. 4 depicts PCE and durability of PSC devices with and without GSCs at the perovskite grains-CTL micro-interface. a-b, J-V curves (a) and EQE spectra with integrated J_{SC} (b) of the champion PSCs with and without GSCs (reverse scan). The device structure is ITO/SnO₂/(FA_{0.95}Cs_{0.05}PbI₃)_{0.975}(MAPbBr₃)_{0.025} perovskite/Spiro-OMeTAD/Au. The inset table in (a) shows the extracted J-V parameters. c, PCEs statistical distributions based on a total of 30 PSCs devices with and without GSCs. d, Thermal cycling durability (between −40 and +85° C.) of PSCs with and without GSCs based on ISOS-T-3 protocol. e, Damp heat durability of PSCs with and without GSCs based on ISOS-D-3 protocol (85° C.; 85% RH). f, MPP tracking of PSCs with/without GSCs based on ISOS-L-11 protocol (one-sun-intensity illumination; in N₂). N₂ gas flow was used for heat dissipation on the device surface, maintaining the temperature at around 40-50° C. The device structure for d-f is ITO/SnO₂/FA_{0.9}Cs_{0.1}PbI₃ perovskite/PTAA/Au. g, Schematic illustration of the strain evolution in perovskite film during −40° C. to 85° C. thermal cycling (left panel), which easily causes the interfacial delamination at the grain-CTL micro-heterointerface in the presence of the GSC because of the accumulated thermal stress on convex ridges, as shown in the right panel. h, Schematic illustration of the role of GSCs at micro-heterointerface in damp-heat test. i, Schematic illustration of the photothermal decomposition that can easily occur at the exposed free surface of GSCs.

FIG. 5 is the Schematic illustration showing the peeling off process and topographic characterization of the bottom interface of perovskite films.

FIG. 6 depicts AFM topographies of SnO₂ film surfaces. The 2×2 μm² AFM height images of the SnO₂ film surface as-prepared (a) and after the peeling off the pristine film from the SnO₂ film (b). The dashed box highlights residual tiny crystal grains on SnO₂ surfaces corresponding to the intragrain holes in FIG. 1a.

FIG. 7 is the top-view SEM images of the bottom surfaces of perovskite films with (a) and without (b) GSCs.

FIG. 8 is the cross-sectional SEM images of perovskite grain-CTL heterointerfaces with (a) and without (b) GSCs.

FIG. 9 depicts the comparison of geometric parameters of SnO₂ top and grain bottom surfaces. Statistical distributions of the length (a) and height (b) localized fluctuations of SnO₂ top micro-surfaces (length, n=25; height, n=50) and grain bottom micro-surfaces (length, n=25; height, n=50) in target group without GSCs. The box plot displays the mean, median line, upper minima and lower maxima, 25-75% box limits with 1.5× interquartile range whiskers.

FIG. 10 depicts AFM topography (1×1 μm²) of the perovskite film bottom surfaces of target samples before (a) and after (b) IPA washing.

FIG. 11 depicts the AFM height images of top surface of perovskite films with (a) and without GSCs (b).

FIG. 12 shows evidence of the existence of GSCs in perovskite films on different substrates. a-d, AFM topography (2×2 μm²) of the FTO substrate surface (a), silicon wafer substrate surface (b), and perovskite bottom surface fabricated on FTO (c) and silicon wafer (d). e-f, The 2D height profile guided by dashed lines in FIG. 12 c (e) and FIG. 12 d (f).

FIG. 13 shows the comparison of height of SnO₂ protrusion and depth of GSCs. a, The statistical distributions of SnO₂ protrusion height and GSC depth based on total 100 measurements. The box plot displays the mean, median line, upper minima and lower maxima, 25-75% box limits with 1.5× interquartile range whiskers. b-c, Schematical illustration of the formation of grains with GSCs of different depths.

FIG. 14 shows evidence of residual perovskite nanofragments on SnO₂ surface corresponding to GBGS on perovskite bottom surfaces. The 2D height profile of residual perovskite nanophase on SnO₂ top surface (guided by dashed line) and the concave in GBG region on perovskite bottom surface (guided by dashed line). The left lower AFM height image of perovskite bottom surface was intercepted from FIG. 1a. The upper right AFM height image of SnO₂ surface was intercepted from FIG. 6b.

FIG. 15 shows the existence of GSCs in perovskite films with KI additives. a, AFM topography of the perovskite film bottom surfaces of samples with additive KI (the same concentration with TFSAP). b, The 2D surface height profile guided by dashed lines in a.

FIG. 16 shows the results of contact angles for calculating surface free energies. Contact angles of H₂O on perovskite films with GSC (a) and without GSCs (b); and of diiodomethane (CH₂12) on perovskite films with GSC (c) and without GSCs (d).

FIG. 17 depicts the mechanism of ion flow and its blocking by anchoring surfactant molecules. Schematic illustration of solid-state ion flow on GB and grain surface via vacancy (a), the role of anchoring surfactant molecules on suppressing the ion flow (b). and the effect of the size of passivation molecule on inhabitation of ion flow (c). The solid-state ion diffusion is mainly mediated by surface/interface vacancies. The functional groups of surfactant molecules with rich electron pairs can passivate defects in perovskite to hinder ion flow. The moving ions must kinetically push the molecules away to enable the diffusion. A larger passivation molecule will be more difficult to be replaced, leading to a more effective inhibition of solid-state ion migration.

FIG. 18 depicts other two surfactant additives minimize GSCs on perovskite bottom surfaces. a, The molecular structures of P123 and NTAC. b-c, The AFM topography of the bottom surfaces of perovskite films at the perovskite-CTL heterointerface with additives of P123 (b) and NTAC (c) into precursor solution.

FIG. 19 depicts steady PL intensity of the Glass/SnO₂/Perovskite structure. The Steady PL intensity of perovskite films with and without GSCs with the structure of Glass/SnO₂/Perovskite.

FIG. 20 depicts pL and TRPL decays of exposed buried perovskite surfaces. a-b, The PL (a) and TRPL (b) spectra of delaminated perovskite films (exposing buried surfaces) with and without GSCs. The photocarrier lifetime (578 ns) fit from the TRPL spectrum of target film is longer than that for the pristine film (99 ns).

FIG. 21 depicts back-side PL and TRPL decays of Quartz/SnO₂/perovskite structure. The back-side PL (a) and TRPL (b) spectra of the samples with and without GSCs (with a structure of Quartz/SnO₂/perovskite). τ_{avg} decreases from 55 ns of pristine film to 18 ns of target film.

FIG. 22 depicts absorption changes of perovskite films under accelerated aging tests. The normalized absorbance variations at the wavelength of 700 nm for perovskite films with and without GSCs under accelerated aging tests (3-sun-intensity illumination; 80° C.).

FIG. 23 depicts PL mapping images of perovskite films after accelerated aging tests. The PL mapping images of perovskite grains with GSCs (a) and without GSCs (b) upon accelerated aging tests (3-sun-intensity illumination; 80° C.) for 120 h.

FIG. 24 depicts XRD intensity of perovskite films after accelerated aging tests. XRD pattern of perovskite films with GSCs and without GSCs upon accelerated aging tests (3-sun-intensity illumination; 80° C.) for 120 h.

FIG. 25 depicts moisture durability of PSCs with and without GSCs. a, Schematic illustration of TFSAP chemical functionalization on moisture tolerance. b, The normalized absorption of perovskite films with and without GSCs on 760 nm wavelength placed in an environmental condition with the humidity of 65-85 RH %. The inset is the optical photograph of perovskite after testing.

FIG. 26 depicts simulated thermal conductivities of micro-heterointerfaces with and without GSCs. The multilayer model for comparing the thermal conductivity with (a) and without GSCs (b), respectively. The height of perovskite and SnO₂ layer is 500 nm, with thickness labeled at the images. The shape of nanogaps induced by GSCs is simplified as a rectangle with a size of 460×10 nm². The thermal conductivity k with GSCs and in the absence of GSCs is compared (c).

FIG. 27 depicts the model diagrams in FEA calculation. In the FEA calculation, the cross-sectional model diagrams of the grain-CTL micro-interface were generated for both cases with (a) and without GSCs (b). The nanogap induced by GSC is set as crescent-shaped structures at the heterointerface with a length of 460 nm and a depth of 10 nm. A longitudinal and a lateral guiding line were labelled in both diagrams.

FIG. 28 shows evidence of GSCs causing interfacial thermal accumulation. The temperature line-profile plot guided by longitudinal (a) and lateral line (b) at the bottom surface of perovskite grain with and without GSCs in FIG. 19.

FIG. 29 shows temperature distributions of the micro-interfaces with external thermal source. The temperature distribution of the grain-CTL micro-interface with (a) and without GSCs (b). The thermal source is set at the bottom surface of the SnO₂ layer. The temperature gradient is set from the bottom surface of the SnO₂ layer (85° C.) to the top surface of the grain (20° C.).

FIG. 30 shows the FEA simulated deformation and thermal stress of micro-heterointerfaces in extreme temperatures in thermal cycling. The 2D elastic deformation and thermal stress distribution of perovskite films with (a, c) and without GSCs (b, d) of thermomechanical FEA results at −40° C. (a, b) and at 85° C. (c, d), respectively. The wireframe represents the device structure without deformation. The bottom surface of ITO layer is set as the rigid boundary considering the restriction of adjacent thick glass substrate to deformation. The micro-heterointerface shows the thermal stress accumulation at the junction point in the presence of GSCs.

FIG. 31 shows the influence of the existence of GSCs on interfacial adhesion strength. Statistical distributions of the normalized delaminated area A_{d} after the delamination process of samples with P123, NTAC and PTFS based on 24 measurements in total. The box plot displays the mean, median line, upper minima and lower maxima, 25-75% box limits with 1.5× interquartile range whiskers.

FIG. 32 shows two molecules with passivation functional groups cannot flatten GSCs on perovskite bottom surfaces. a-b, The molecular structures of SDBS (a) and PTFS (b). c-d, The AFM topography images of the bottom surfaces of perovskite films at the perovskite-CTL heterointerface with additives of SDBS (c) and PTFS (d) into precursor solution.

FIG. 33 shows the mechanism of flattened GSCs amplifying benefits on interfacial adhesion with the I-SAM layer. Schematic illustration of the interfacial adhesion of perovskite grains with (a) and without GSC (b). The I-SAM with —I terminated group can form a hydrogen bond with perovskite. The concaved central surface of grains with GSCs cannot form the hydrogen bond because of the existence of nanogaps at the micro-heterointerface.

FIG. 34 shows cross-sectional SEM images of perovskite films after thermal cycling tests. The cross-sectional SEM images of perovskite films with (a) and without GSCs (b) after 300 cycles of thermal cycling tests (−40 to +85° C.).

FIG. 35 shows evidence of chemical passivation not dominating the optoelectronic properties improvement. a, The PL spectra of delaminated perovskite films (exposing buried surfaces) with GSCs, with SDBS, and with PTFS. b, PCE statistics of PSCs made with SDBS (n=25) and PTFS (n=25). The box plot displays the mean, median line, upper minima and lower maxima, 25-75% box limits with 1.5× interquartile range whiskers.

FIG. 36 shows evidence of GBGs flattening not dominating PCE and stability improvement. The AFM images of perovskite bottom surface (a) and statistical distribution of GBG side-angle θ (n=174) (b), J-V curve (c) and operational stability at MPP (d) of perovskite films/devices with flattened GBG. The inset table in (c) shows the extracted J-V parameters.

FIG. 37 shows the influence of P123 with flattening GSCs on device PCE. The PCE statistics of PSCs made without (pristine, n=15) and with Pluronic® P123 (n=15). The box plot displays the mean, median line, upper minima and lower maxima, 25-75% box limits with 1.5× interquartile range whiskers.

FIG. 38 shows temperature variation information during the thermal cycling test. The temperature variation curve of a cycle (54 min) during the thermal cycling test.

FIG. 39 shows the evidence of negligible spatial differences in the perovskite bottom and SnO₂ top surfaces. Statistical distributions Rₐ values for each AFM image (corresponding locations) of perovskite bottom surface (n=10) and SnO₂ surface (n=10). The box plot displays the mean, median line, upper minima and lower maxima, 25-75% box limits with 1.5× interquartile range whiskers.

FIG. 40 depicts Table 1 showing the contact angles of water (H₂O) and diiodomethane (CH₂12) on perovskite films with and without GSCs.

FIG. 41 depicts Table 2 showing the dispersive (γₗᵥ^{P}) and polar parts (γₗᵥ^{D}) of the surface tension of two probing liquids H₂O and CH₂12.

FIG. 42 depicts Table 3 showing the thermal conductivity k, heat capacity at constant pressure C_{P}, density ρ, Young's module M, Poisson's ratio ν, and thermal expansion coefficient α in thermomechanical FEA.

### DETAILED DESCRIPTION

### Definitions

Throughout the present disclosure, unless the context requires otherwise, the word “comprise” or variations such as “comprises” or “comprising”, will be understood to imply the inclusion of a stated integer or group of integers but not the exclusion of any other integer or group of integers. It is also noted that in this disclosure and particularly in the claims and/or paragraphs, terms such as “comprises”, “comprised”, “comprising” and the like can have the meaning attributed to it in U.S. Patent law; e.g., they can mean “includes”, “included”, “including”, and the like; and that terms such as “consisting essentially of” and “consists essentially of” have the meaning ascribed to them in U.S. Patent law, e.g., they allow for elements not explicitly recited, but exclude elements that are found in the prior art or that affect a basic or novel characteristic of the present invention.

Furthermore, throughout the present disclosure and claims, unless the context requires otherwise, the word “include” or variations such as “includes” or “including”, will be understood to imply the inclusion of a stated integer or group of integers, but not the exclusion of any other integer or group of integers.

The use of the singular herein includes the plural (and vice versa) unless specifically stated otherwise. In addition, where the use of the term “about” is before a quantitative value, the present teachings also include the specific quantitative value itself, unless specifically stated otherwise. As used herein, the term “about” refers to a ±10%, ±7%, ±5%, ±3%, ±1%, or ±0% variation from the nominal value unless otherwise indicated or inferred.

The terms “weight percent,” “wt-%,” “percent by weight,” “% by weight,” and variations thereof, as used herein, refer to the concentration of a substance as the weight of that substance divided by the total weight of the composition and multiplied by 100. It is understood that, as used here, “percent,” “%,” and the like are intended to be synonymous with “weight percent,” “wt-%,” etc.

The processes and compositions of the present disclosure may comprise, consist essentially of, or consist of the components and ingredients of the present disclosure as well as other ingredients described herein. As used herein, “consisting essentially of means that the methods and compositions may include additional steps, components or ingredients, but only if the additional steps, components or ingredients do not materially alter the basic and novel characteristics of the claimed processes and compositions.

The term of “perovskite solar cell(s)” used herein refers to solar cells that use a perovskite-structured material as the light-absorbing layer. When light is incident on the perovskite material, it excites electrons in the material, creating electron-hole pairs. The perovskite material has excellent charge-transport properties, allowing the electrons and holes to be separated and transported to the electrodes, where they can be collected as electrical current.

The perovskite solar cell in a normal structure typically consists of a transparent conductive oxide (TCO) layer, a hole transport layer (HTL), a perovskite light-absorbing layer, an electron transport layer (ETL), and a metal electrode. In a perovskite solar cell having an inverted structure, the order of the layers is reversed compared to the normal structure, with the TCO layer followed by the ETL, the perovskite layer, the HTL, and the metal electrode.

The existing perovskite compound films in PSCs are invariably polycrystalline, consisting of a dense packing of individual grains. As a result, the heterointerface of perovskite compound film with the charge-transport layer (CTL) can be viewed as an ensemble of the segments of grain-CTL micro-heterointerfaces. The properties of each segment of grain-CTL micro-heterointerface accumulatively determine the properties of the overall heterointerface between the perovskite compound film and the CTL layer in PSCs. Therefore, it is critical to ensure the high microstructural integrity of individual grain-CTL micro-heterointerfaces so that a more ideal perovskite heterointerface can be formed.

Using atomic-force microscopy and depth profiling, the present inventors revealed a general existence of grain surface concaves (GSCs), a type of under-explored microstructure in the art, on individual grain surfaces of representative perovskite compound films. These GSCs inevitably lead to buried nanoscale gaps between the grain centre and the underneath CTL. Due to their relatively small depths as compared to the sizes of individual grains and the height contrast of grain boundary grooves (GBGs), it is not surprising that GSCs have been neglected in the morphological and microstructural studies of PSCs in the past years.

It has been found that the formation of these GSCs is attributed to the solid-state ion plastic flow from the GBGs and the grain surface center to the convex ridges, which are triggered by thermal-driven grain boundary (GB) grooving and grain-coalescence-induced biaxial tensile strain (BTS), respectively. More importantly, GSCs impart profound negative effects on carrier-exacting, chemical, and thermomechanical properties of perovskite heterointerface. Owing to the layer-by-layer processing of PSC, any negative effects on the structural and functional integrities on the perovskite top surface side may be compensated by a conformal deposition of sequential layers.

This study thus focuses on the buried bottom perovskite heterointerface. To alleviate the negative effects of GSCs, certain surfactants can be added to manipulate the interfacial energetics on grain surfaces and GBs to simultaneously suppress GB grooving and BTS. As a result, perovskite films are produced with minimum GSCs observed on individual grains bottom surfaces, leading to the robust and stable grain-CTL micro-heterointerfaces. PSCs incorporating this microstructural engineering deliver a high power conversion efficiency (PCE) of 25.5%. The PCEs of PSCs with the removal of GSCs can retain 83%, 90% and 90% in device stability tests following international consensus protocols of ISOS-T-3 (300 cycles), ISOS-D-3 (660 h), and ISOS-L-11 (1290 h), respectively, demonstrating the merits of GSC engineering.

The present disclosure provides a perovskite layer comprising a perovskite compound and a surfactant, wherein the perovskite compound is represented by Formula 1:

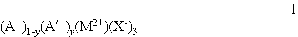

wherein y is 0.01-0.99;
M²⁺ is Pb²⁺, Sn²⁺, or Ge²⁺;
each of A⁺ and A′⁺ is independently Cs⁺, Rb⁺, CH₃NH₃⁺, CH₃CH₂NH₃⁺, H(C═NH₂)NH₂⁺, or Me(C═NH₂)NH₂⁺; and
X⁻ for each instance is independently F⁻, Cl⁻, Br⁻, or I⁻, wherein A⁺ and A′⁺ are the same or different; and
the surfactant comprises a sulfonate surfactant, an alcohol alkoxylate surfactant, a quaternary ammonium surfactant, or mixtures thereof.

In certain embodiments, the sulfonate surfactant comprises a sulfonate group substituted by a perhalogenated C₄-C₁₂ alkyl. In certain embodiments, the sulfonate surfactant comprises a sulfonic group substituted by a perhalogenated C₄-C₁₀ alkyl or a perhalogenated C₄-C₈ alkyl. In certain embodiments, the perhalogenated C₄-C₁₂ alkyl is linear or branched, unsubstituted or substituted, saturated or unsaturated alkyl. In certain embodiments, the sulfonate surfactant comprises a sulfonate group substituted by a perhalogenated n-butyl, n-pentyl, n-hexyl, n-heptyl, n-octyl, n-nonyl, n-decyl, n-undecyl or n-dodecyl substituent.

In certain embodiments, the sulfonate surfactant is a fluorocarbon-based surfactant. In certain embodiments, the sulfonate surfactant is perfluoroalkane sulfonate. In certain embodiments, the perfluoroalkane sulfonate is perfluorohexane sulfonate, perfluorobutane sulfonate, perfluorodecane sulfonate or mixtures thereof.

In certain embodiments, the quaternary ammonium surfactant comprises one or more C₁-C₁₆ alkyl substituents. In certain embodiments, the quaternary ammonium surfactant comprises one or more C₄-C₁₂ alkyl substituents, or one or more C₆-C₁₀ alkyl substituents. In certain embodiments, the C₁-C₁₆ alkyl is linear or branched, unsubstituted or substituted, saturated or unsaturated alkyl. In certain embodiments, the quaternary ammonium surfactant comprises methyl, ethyl, n-propyl, isopropyl, n-butyl, isobutyl, n-pentyl, isopentyl, n-hexyl, n-heptyl, n-octyl, n-nonyl, n-decyl, n-undecyl or n-dodecyl substituent.

In certain embodiments, the surfactant comprises one or more of potassium tridecafluorohexane-1-sulfonate (TFSAP), sodium tridecafluorohexane-1-sulfonate, potassium nonafluorobutane-1-sulfonate, sodium nonafluorobutane-1-sulfonate, potassium henicosafluorodecane-1-sulfonate, sodium henicosafluorodecane-1-sulfonate, a poly(ethylene oxide)/poly(propylene oxide) (EO/PO) block copolymer, or N,N,N-trimethyloctan-1-aminium chloride

In certain embodiments, M²⁺ is Pb²⁺; and each of A⁺ and A′⁺ is independently Cs⁺, CH₃NH₃⁺, or H(C═NH₂)NH₂⁺.

In certain embodiments, the perovskite layer comprises (H(C═NH₂)NH₂⁺)_{1-y}(Cs⁺)_{y}(Pb²⁺)(I⁻)₃, wherein y is 0.01-0.99.

In certain embodiments, the perovskite layer comprises a perovskite of Formula 2:

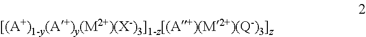

wherein y is 0.01-0.99;
z is 0.01-0.99;
M²⁺ is Pb²⁺, Sn²⁺, or Ge²⁺;
M′²⁺ is Pb²⁺, Sn²⁺, or Ge²⁺;
each of A⁺, A′⁺, and A″⁺ is independently Cs⁺, Rb⁺, CH₃NH₃⁺, CH₃CH₂NH₃⁺, H(C═NH₂)NH₂⁺, or Me(C═NH₂)NH₂⁺; and
X⁻ and Q⁻ for each instance is independently F⁻, Cl⁻, Br⁻, or I⁻, wherein A⁺ and A′⁺ are the same or different.

In certain embodiments, each of M²⁺ and M′²′ is Pb²⁺; each of A⁺ and A′⁺ is independently Cs⁺, CH₃NH₃⁺, or H(C═NH₂)NH₂⁺; and A″⁺ is CH₃NH₃⁺.

In certain embodiments, the perovskite layer comprises [(H(C═NH₂)NH₂⁺)_{1-y}(Cs⁺)_{y}(Pb²⁺)(I⁻)₃]_{1-z}[(CH₃NH₃⁺)(Pb²⁺)(Br⁻)₃]_{z}, wherein y is 0.01-0.99 and z is 0.01-0.99.

In Formula 1 and Formula 2, y is 0.01, 0.05, 0.10, 0.15, 0.20, 0.25, 0.30, 0.35, 0.40, 0.45, 0.50, 0.55, 0.60, 0.65, 0.70, 0.75, 0.80, 0.85, 0.90, 0.95, or 0.99. In Formula 1 and Formula 2, z is 0.01, 0.05, 0.10, 0.15, 0.20, 0.25, 0.30, 0.35, 0.40, 0.45, 0.50, 0.55, 0.60, 0.65, 0.70, 0.75, 0.80, 0.85, 0.90, 0.95, or 0.99.

In certain embodiments, the perovskite compound film comprises FA_{0.9}Cs_{0.1}PbI₃, (FA_{0.95}Cs_{0.05}PbI₃)_{0.975}(MAPbBr₃)_{0.025}, FAPbI₃, Cs_{0.05}FA_{0.95}PbI₃, Cs_{0.17}FA_{0.83}PbI₃, Cs_{0.05}FA_{0.85}MA_{0.1}PbI₃, Cs_{0.05}FA_{0.81}MA_{0.14}PbI_{2.55}Br_{0.45}, Cs_{0.05}(FA_{0.95}MA_{0.05})_{0.95}Pb(I_{2.95}Br_{0.05})₃, or any mixture thereof.

In certain embodiments, the perovskite layer comprises a plurality of perovskite grains, and a bottom surface of each of the plurality of perovskite grains comprises a single grain surface concave (GSC) and a convex ridge around the GSC, and wherein the average angle between the line connecting the apex of the convex ridge to the center of the GSC and a top surface opposite to the bottom surface of the grain is 0°-1.5°.

The geometric parameter is proposed by the present inventor to assess the microstructure of the perovskite compound grains, thus roughly elaborating the degree of the curving from an ideally flat surface.

In the present disclosure, the bottom surface of a perovskite grain is the surface in contact with the electron transport layer of a perovskite solar cell with a normal structure, or is the surface in contact with the hole transport layer of a perovskite solar cell with an inverted structure.

In certain embodiments, the perovskite grains have an average angle ξ of 0° to 1°, or 0° to 0.5°. In certain embodiments, the perovskite grains have an angle ξ of 0°, 0.1°, 0.2°, 0.3°, 0.4°, 0.5°, 0.6°, 0.7°, 0.8°, 0.9°, 1.0°, 1.1°, 1.2°, 1.3°, 1.4°, or 1.5°, or any value ranges therebetween.

In the present disclosure, the perovskite grains in the perovskite layer have nearly flat surfaces, which is beneficial for ensuring the continuity and flatness of the heterointerface between the perovskite compound film and the charge transport layer (CTL), and forming a more ideal heterointerface.

In addition to the geometric parameter, another geometric parameter θ is further used to assess the microstructure of the perovskite compound grains. In certain embodiments, the perovskite layer comprises a plurality of perovskite grains and a grain-boundary grooving (GBG) between the bottom surfaces of each of adjacent perovskite grains, the GBG is surrounded by edges of the adjacent perovskite grains as the GBG sidewall, and the average angle θ between the tangent to the GBG sidewall and a top surface opposite to the bottom surface of the grain is 0°-15°.

In certain embodiments, the perovskite grains have an average angle θ of 0° to 12°, or 0° to 10°. In certain embodiments, the grains in the perovskite compound film have an angle θ of 0°, 0.5°, 1.0°, 1.5°, 2.0°, 2.5°, 3.0°, 3.5°, 4.0°, 4.5°, 5.0°, 5.5°, 6.0°, 6.5°, 7.0°, 7.5°, 8.0°, 8.5°, 9.0°, 9.5°, 10.0°, 10.5°, 11.0°, 11.5°, 12.0°, 12.5°, 13.0°, 13.5°, 14.0°, 14.5°, or 15.0°, or any value ranges therebetween.

Depending on processes and conditions for producing the perovskite layer, perovskite grains can form either monolayer or multilayer structures. For example, through slot-die coating processes and the regulation of specific precursor solutions, perovskite compound films with large-sized grains in a monolayer structure can be prepared. Monolayer structure is more suitable for reducing grain boundary defects and optimizing carrier transport pathways, especially in large-area fabrication. The formation of multilayer structure is closely related to crystallization kinetics, the stability of the precursor solution, and the solvent evaporation rate in the preparation process. For example, inconsistent crystallization rates between the upper and lower layers may lead to the stacking of grains in multiple layers. Multilayer structure can also enhance efficiency by optimizing the combination of different bandgap perovskite layers.

In certain embodiments, the perovskite grains form a single layer in the perovskite compound film. In certain embodiments, the perovskite grains form multi-layers in the perovskite compound film.

In certain embodiments, the perovskite grains have an average size in the range of 50-900 nm, 100-500 nm, or 300-500 nm. In certain embodiments, the perovskite compound grains have a size of 50 nm, 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, or any value ranges therebetween.

The present disclosure further provides a method for producing the perovskite layer, the method comprising:
providing a perovskite precursor solution comprising one or more metal salts each independently represented by the formula MX₂, two or more salts each independently represented by the formula AZ, the surfactant, and a solvent, wherein M is Pb²⁺, Sn²⁺, or Ge²⁺, A is Cs⁺, Rb⁺, CH₃NH₃⁺, CH₃CH₂NH₃⁺, H(C═NH₂)NH₂⁺, or Me(C═NH₂)NH₂⁺, X for each instance is independently F⁻, Cl⁻, Br⁻, or I⁻, and Z for each instance is independently F⁻, Cl⁻, Br⁻, or I⁻;
depositing the perovskite precursor solution on a surface of a charge transport layer to form a wet film; and
annealing the wet film to form the perovskite layer.

The perovskite precursor solution may be deposited by the methods such as spin coating, blade coating, spray coating, slot-die coating, inkjet printing and vapor deposition. In certain embodiments, the perovskite precursor solution is deposited by spin coating.

In certain embodiments, the solvent used herein can comprise organic solvents such as dimethylformamide (DMF), dimethyl sulfoxide (DMSO), 7-butyrolactone (GBL), N-methyl-2-pyrrolidone (NMP), acetonitrile (ACN), isopropanol (IPA), chlorobenzene (CB), anisole, N,N′-dimethylpropyleneurea (DMPU), toluene, ethanol, methanol, or mixtures thereof.

The selection and combination of these solvents can be optimized based on the specific perovskite composition and preparation process to achieve the best film quality and device performance. In certain embodiments, the solvent used herein is DMF, DMSO or a mixture thereof.

In certain embodiments, the method can optionally comprise: treating the wet film with an anti-solvent or other additive to control morphology and grain size as well as enhance the stability of the film. The anti-solvent can comprise chlorobenzene, toluene, diethyl ether (DE), ethyl acetate (EA), isopropyl alcohol (IPA), anisole, tert-butyl alcohol or mixtures thereof.

Annealing the perovskite wet film may significantly impact the film's quality and the device's performance. Optimal annealing conditions can vary depending on the specific perovskite composition and the desired film properties. In certain embodiments, the wet film is subjected to annealing at a temperature of 100° C.-200° C. or 100° C.-180° C. In certain embodiments, the wet film is subjected to annealing at a temperature of 100° C., 110° C., 120° C., 130° C., 140° C., 150° C., 160° C., 170° C., 180° C., 200° C. or any value ranges therebetween.

In certain embodiments, the wet film is subjected to annealing for a time period of 5-60 min, or 5-40 min. In certain embodiments, the wet film is subjected to annealing for a time period of 5 min, 10 min, 15 min, 20 min, 25 min, 30 min, 35 min, 40 min, 45 min, 50 min, 55 min, 60 min, or any value ranges therebetween.

In certain embodiments, the perovskite precursor solution comprises (Cs⁺)(I⁻), (H(C═NH₂)NH₂⁺)(I⁻), (Pb²⁺)(I⁻)₂, and sodium tridecafluorohexane-1-sulfonate.

In certain embodiments, the perovskite precursor solution comprises (Cs⁺)(I⁻), (H(C═NH₂)NH₂⁺)(I⁻), (CH₃NH₃⁺)(Cl⁻), (Pb²⁺)(I⁻)₂, (CH₃NH₃⁺)(Pb²⁺)(Br⁻)₃, and sodium tridecafluorohexane-1-sulfonate.

In certain embodiments, the surfactant has a concentration of 0.1-5 mg/ml in the perovskite precursor solution. In certain embodiments, the surfactant has a concentration of 0.1 mg/ml, 0.2 mg/ml, 0.3 mg/ml, 0.4 mg/ml, 0.5 mg/ml, 0.6 mg/ml, 0.7 mg/ml, 0.8 mg/ml, 0.9 mg/ml, 1.0 mg/ml, 1.1 mg/ml, 1.2 mg/ml, 1.3 mg/ml, 1.4 mg/ml, 1.5 mg/ml, 1.6 mg/ml, 1.7 mg/ml, 1.8 mg/ml, 1.9 mg/ml, 2.0 mg/ml, 2.1 mg/ml, 2.2 mg/ml, 2.3 mg/ml, 2.4 mg/ml, 2.5 mg/ml, 2.6 mg/ml, 2.7 mg/ml, 2.8 mg/ml, 2.9 mg/ml, 3.0 mg/ml, 3.1 mg/ml, 3.2 mg/ml, 3.3 mg/ml, 3.4 mg/ml, 3.5 mg/ml, 3.6 mg/ml, 3.7 mg/ml, 3.8 mg/ml, 3.9 mg/ml, 4.0 mg/ml, 4.1 mg/ml, 4.2 mg/ml, 4.3 mg/ml, 4.4 mg/ml, 4.5 mg/ml, 4.6 mg/ml, 4.7 mg/ml, 4.8 mg/ml, 4.9 mg/ml, or 5 mg/ml, or any value ranges therebetween, in the perovskite precursor solution.

In certain embodiments, the one or more metal salts each independently represented by the formula MX₂ have a concentration of 0.5-2.0 M in the perovskite precursor solution. In certain embodiments, the one or more metal salts each independently represented by the formula MX₂ have a concentration of 0.5 M, 0.6 M, 0.7 M, 0.8 M, 0.9 M, 1.0 M, 1.1 M, 1.2 M, 1.3 M, 1.4 M, 1.5 M, 1.6 M, 1.7 M, 1.8 M, 1.9 M, 2.0 M, or any value ranges therebetween, in the perovskite precursor solution.

In certain embodiments, the two or more salts each independently represented by the formula AZ have a concentration of 0.5-2.0 M in the perovskite precursor solution. In certain embodiments, the two or more salts each independently represented by the formula AZ have a concentration of 0.5 M, 0.6 M, 0.7 M, 0.8 M, 0.9 M, 1.0 M, 1.1 M, 1.2 M, 1.3 M, 1.4 M, 1.5 M, 1.6 M, 1.7 M, 1.8 M, 1.9 M, 2.0 M, or any value ranges therebetween, in the perovskite precursor solution.

In certain embodiments, the method for producing the perovskite layer comprises:
dissolving (Cs⁺)(I⁻), (H(C═NH₂)NH₂⁺)(I⁻) and (Pb²⁺)(I⁻)₂ along with TFSAP in a solvent comprising DMF and DMSO to prepare a perovskite precursor solution;
depositing the perovskite precursor solution onto a surface of an ETL on a substrate to form a wet film;
adding an anti-solvent into the wet film; and
annealing the wet film at a temperature of 150-180° C. for 5-15 min.

In certain embodiments, the method for producing the perovskite layer comprises:
dissolving (Cs⁺)(I⁻), (H(C═NH₂)NH₂⁺)(I⁻), (CH₃NH₃⁺)(Cl⁻), (Pb²⁺)(I⁻)₂, (CH₃NH₃⁺)(Pb²⁺)(Br⁻)₃, along with TFSAP in a mixed solvent comprising DMF and DMSO to prepare a perovskite precursor solution;
depositing the perovskite precursor solution onto a surface of an ETL on a substrate to form a wet film;
adding an anti-solvent into the wet film; and
annealing the wet film at a temperature of 100-120° C. for 30-40 min.

The present disclosure further provides a photoelectric device comprising the perovskite compound film as described above. The photoelectric device comprises perovskite solar cell (PSC), perovskite light-emitting diodes, perovskite lasers, and perovskite photodetectors.

The addition of specific surfactants to perovskite films results in enhanced power conversion efficiency (PCE) for the photoelectric device containing the perovskite compound film in the present disclosure. In particular, for perovskite solar cells (PSCs), the power conversion efficiency can be increased to up to 23.5-25.5%.

In certain embodiments, the perovskite solar cell can have a normal structure, comprising a transparent or translucent conductive substrate, an electron transport layer, the perovskite compound film as described above, a hole transport layer and a metal electrode that are deposited sequentially. In certain embodiments, the perovskite solar cell can have a revert structure, comprising a transparent or translucent conductive substrate, a hole transport layer, the perovskite compound film as described above, an electron transport layer and a metal electrode that are deposited sequentially.

The transparent or translucent conductive substrate may be cleaned in advance by ultrasonication in solvents such as isopropanol, acetone and water. The substrate can also be treated with UV light for surface activation.

The transparent conductive oxide in the conductive substrate is selected from the group consisting of an indium tin oxide (ITO), a zinc oxide, a doped tin oxide, and a doped zinc oxide, such as a fluorine-doped tin oxide (FTO), or an aluminum-doped tin oxide (AZO), etc.

In certain embodiments, the transparent conductive oxide can include 90 wt % to 100 wt % of ITO, FTO, or AZO. In certain embodiments, the transparent conductive oxide can be composed primarily of ITO, FTO, or AZO. In certain embodiments, transparent conductive oxide is ITO.

In certain embodiments, a thickness of the perovskite compound film is 100 nm to 1000 nm, such as 100 nm, 200 nm, 300 nm, 400 nm, 500 nm, 600 nm, 700 nm, 800 nm, 900 nm, or 1000 nm.

Materials for forming the electron transport layer and the hole transport layer can be those commonly used in a perovskite solar cell. In certain embodiments, the electron transport layer may be formed by materials selected from titanium dioxide (TiO₂), tin oxide (SnO₂), zinc oxide (ZnO), zinc tin oxide (Zn₂SnO₄), [6,6]-phenyl-C₆₁-butyric acid methyl ester (PCBM), and perylene diimides (PDI). In certain embodiments, the hole transport layer may be formed by materials selected from 2,2′,7,7′-tetrakis(N,N-di-p-methoxyphenylamine)-9,9′-spirobifluorene (Spiro-OMeTAD), poly(triarylamine) (PTAA), poly(3,4-ethylenedioxythiophene) polystyrene sulfonate (PEDOT:PSS), poly(3-hexylthiophene-2,5-diyl) (P3HT), nickel oxide (NiOₓ), Copper(I) thiocyanate (CuSCN), 6,13-bis(triisopropylsilylethynyl)pentacene (TIPS-Pentacene), and copper phthalocyanine (CuPc).

In certain embodiments, the perovskite solar cell comprises an interfacial glue layer between the perovskite compound film and the charge transport layer (electron transport layer or hole transport layer). The interfacial glue may be selected from (3-iodopropyl)trimethoxysilane (Si(OCH₃)₃(CH₂)₃I), potassium tetrafluoroborate (KBF₄), trifluoromethane-sulfonamide (CF₃SO₂NH₂), aminopropyltriethoxysilane (H₂NCH₂CH₂CH₂Si(OC₂H₅)₃), polyhexamethylene guanidine hydrochloride, and 5,6-isopropyridine-L-ascorbic acid.

### EXAMPLES

### Materials and Methods

### 1. Raw Materials.

Tin (IV) oxide (15 wt. % in H₂O colloidal dispersion) was purchased from Alfa Aesar (USA). PbI₂ (99.99%), (3-iodopropyl)trimethoxysilane (Si(OCH₃)₃(CH₂)₃I, 95%) and 4-Isopropyl-4′-methyldiphenyliodonium Tetrakis(pentafluorophenyl)borate (TPFB, >98%) were purchased from TCI (Japan). HC(NH₂)₂I (FAI, >99.99%), methylammonium chloride (MACl, >99.99%), 4-methoxy-phenethylammonium-iodide (MeO-PEAI, >99.99%) and FK 209 Co(III) TFSI salt were purchased from Greatcell Solar (Australia). CsI (99.999%) and PTAA was purchased from Xi'an Yuri Solar (China). Spiro-OMeTAD (99.8%) was purchased from Borun Chemical (China). Tridecafluorohexane-1-sulfonic acid potassium salt (TFSAP, 95%) was purchased from Macklin (China). Potassium chloride (KCl, 99.0-100.5%), poly(methylmethacrylate) (PMMA), 4-tert-butylpyridine (t-bp, 96%), Bis(trifluoromethane) sulfonimide lithium salt (99.95%), PbBr₂ (>99%), dimethyl sulfoxide (DMSO, 99.9%), dimethylformamide (DMF, 99.8%), chlorobenzene (CB, 99.8%), toluene (TB, 99.8%), acetonitrile (ACN, >99.9%), Diethyl ether (DE, 99%) and isopropyl alcohol (IPA, 99.5%) were acquired from Merck (USA). Dichloromethane was purchased from International Laboratory USA.

### 2. Device Fabrication.

2-1. Fabrication of Basic Devices with Pristine Perovskite Films

The pre-patterned ITO substrates were cleaned by sonication with deionized water, acetone, and isopropanol for 15 min each. All substrates were cleaned by ultraviolet (UV)/ozone treatment for 30 min after drying by N₂ gas flowing. The SnO₂ colloid precursor was diluted with deionized water (v/v 1:5), and was spin-coated onto ITO substrates at 3000 rpm for 30 s with a subsequent annealing at 180° C. for 30 min. The as-prepared SnO₂ film was treated by UV/ozone for 10 min before subsequent deposition. KCl solution (3 mg/mL in DI water) was spin-coated on the SnO₂ layer at a speed of 4000 rpm for 20 s with a subsequent annealing at 100° C. for 10 min.

The perovskite layer was formed by FA-Cs compounds of FA_{0.9}Cs_{0.1}PbI₃ or (FA_{0.95}Cs_{0.05}PbI₃)_{0.975}(MAPbBr₃)_{0.025}, respectively, which were used in different devices. Procedures for preparing the perovskite layer are described as follows.

Preparation of FA_{0.9}Cs_{0.1}PbI₃ perovskite layer (pristine film 1). The perovskite precursor solution was prepared by dissolving 36 mg CsI, 154.7 mg FAI and 461 mg PbI₂ in 1 mL mixed DMF-DMSO solvent (v/v 7:3). The precursor solution was stirred at room temperature overnight and then filtered before using. A 50 μL precursor solution was dripped onto the SnO₂ ETL surface prepared above. The spin-coating process was carried out in three steps: 500 rpm for 5 s, 3000 rpm for 10 s, and finally 5000 rpm for 30 s. At the 10 s of the final step, 400 μL of toluene was dropped onto the substrate within Is. The deposited film was immediately annealed on a 170° C. hotplate for 6 min. This pristine film 1 was used for fundamental investigation.

Preparation of (FA_{0.95}Cs_{0.05}PbI₃)_{0.975}(MAPbBr₃)_{0.025} perovskite layer (pristine film 2). The perovskite precursor solution was prepared by dissolving 228.8 mg FAI, 18.2 mg CsI, 33.7 mg MACl, 705.3 mg PbI₂ and 18.2 mg MAPbBr₃ single crystal in 1 mL mixed DMF-DMSO (v/v 8:1). MAPbBr₃ single crystal was synthesized by mixing MABr and PbBr₂ in a 1:1 molar ratio with a concentration of 0.2 M in DMF solvent and capturing the single crystal with dichloromethane antisolvent. Then 60 μL precursor solution was dripped onto the SnO₂ layer, followed by a two-stage spin-coating process (1000 rpm for 10 s and 4000 rpm for 30 s). 800 μL diethyl ether was dropped onto the spinning perovskite surface within 2 s at the 15 s of the second step. The wet film was annealed on a 100° C. hotplate for 40 min. After the film had been cooled to room temperature, 50 μL MeO-PEAI (dissolved in IPA; 4 mg/ml) passivation layer was spin-coated onto the perovskite layer at 5000 rpm for 30 s, followed by annealing at 100° C. for 5 min to improve overall V_{OC} of all PSC devices. This pristine film 2 was used for high-PCE device demonstration.

The HTL solution was prepared by mixing 1 mL Spiro-OMeTAD solution (91 mg/mL in chlorobenzene) with 36 μL 4-tertbutylpyridine, 21 μL Li-TFSI solution (520 mg/mL in acetonitrile) and 16 μL FK209 solution (375 mg/mL in acetonitrile). Then 50 μL of HTL solution was spin-coated onto the perovskite layer at 3000 rpm for 30 s. Spiro-OMeTAD layer was placed in a drying oven (humidity less than 5%) for 2 days to promote the oxidation process of Spiro-OMeTAD. For the stability test, PTAA was used to replace Spiro-OMeTAD. Herein 50 μL of PTAA solution (30 mg/ml in CB with 3 mg/ml TPFB doping) was spin-coated onto the perovskite layer at 2000 rpm for 30 s. Finally, 80 nm Au was deposited by thermal evaporation. For device encapsulation, we applied UV glues at the device edges, following by a typical curing process.

2-2. Fabrication of Devices with Target Perovskite Films

The fabrication of device was the same as that of basic devices, except that the perovskite film was modified with the surfactant of TFSAP.

The perovskite films modified with the surfactant of TFSAP (target films) were prepared as below. In one example, TFSAP mother solution was prepared in mixed DMF-DMSO solvent and was added into the perovskite precursor solution containing perovskite compound of FA_{0.9}Cs_{0.1}PbI₃, which was then deposited on a surface of a charge transport layer to form target film 1. In another example, TFSAP mother solution was prepared in mixed DMF-DMSO solvent and was added into the perovskite precursor solution containing (FA_{0.95}Cs_{0.05}PbI₃)_{0.975}(MAPbBr₃)_{0.025}, which was then deposited on a surface of a charge transport layer to form target film 2. The concentration TFSAP in perovskite precursor solution is 0.6 mg/mL. The target films 1 and 2 were deposited in a nitrogen glove box with O₂<1 ppm, H₂O<1 ppm. The perovskite precursor solutions were prepared with the same procedures as for the basic devices above.

### 3. Characterization Method of Materials and Device.

The AFM topographic images of the perovskite layers were acquired using the Multimode 8 (Bruker, USA) with a RTESP-300 tip in non-contact tapping mode. A scanning electron microscope (Gemini 1530, LEO, Zeiss, Germany) was used for characterizing the top-view surface and cross-sectional SEM images. XRD (D8 Advance, Bruker, USA) with Cu Kα radiation (λ=1.5406 Å) was used to characterize the crystallographic structure of the perovskite layer. The steady-state PL and TRPL signals were directed into a spectrograph (Ando Kymera 328i) with the excitation of a 375 nm picosecond laser (LDH-D-C-375, PicoQuant, Germany). The PL signal was further collected by an electron multiplying charge-coupled device (EMCCD; Andor iXon Life 888, Oxford Instruments, UK) for the steady-state PL and a single-photon avalanche photodiode for the TRPL measurements. For the measurement of PL from the bottom side of the fabricated perovskite films, a quartz was used to replace the ITO glass substrate to minimize light scattering. PL mapping images were captured by a digital microscope camera (Nikon DS-Qi2) with a UV light source (250-450 nm) and a filter (long pass after 726 nm). UV-vis spectra were acquired by a commercial UV-visible spectrophotometer (Cary 300, Agilent, USA).

The J-V characterization for perovskite devices was measured by a source meter (2612, Keithley, USA) under an AM 1.5G spectrum (one-sun illumination; 100 mW cm⁻²) generated by a solar simulator (Sirius-SS, Zolix, China) in a glovebox filled with nitrogen. All devices were measured in a reverse scan (from 1.3 V to −0.02 V) with a step size of 0.02 V and a delay time of 10 ms. The active area defined by a shadow mask was 0.05 cm². The light intensity was calibrated by an Oriel® reference solar cell accredited by NIST to the ISO-17025 standard. External quantum efficiency spectra were recorded at a chopping frequency of 165 Hz in AC mode on a solar cell quantum efficiency measurement system (QE-R3011, Enlitech, China). For the MPP tracking test of PSC devices, devices were placed inside a test chamber in a nitrogen glovebox, with a continuous flow of N₂ gas to maintain the temperature of test chamber to 40-50° C., following the ISOS-L-11 protocol. The devices operated under bias at their maximum power points, with data points collected at regular intervals. For the thermal cycling stability test (ISOS-T-3 protocol), encapsulated devices were placed in an environmental chamber controlled by the self-defined program. The temperature was set to be cycled between −40° C. and +85° C., with each cycle lasting 54 min. The temperature variation curve of a cycle (54 min) during the thermal cycling test is shown in FIG. 38. The humidity was controlled to below 20% RH. The PCE test of devices was in the nitrogen glovebox on room temperature. For the damp heat stability test (ISOS-D-3 protocol), encapsulated devices were placed in an environmental chamber with a temperature of 85° C. and a humidity of 85% RH. The PCE test of devices was also in the nitrogen glovebox on room temperature.

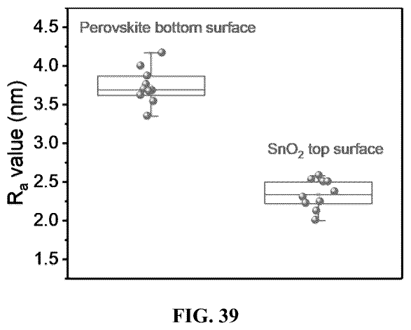

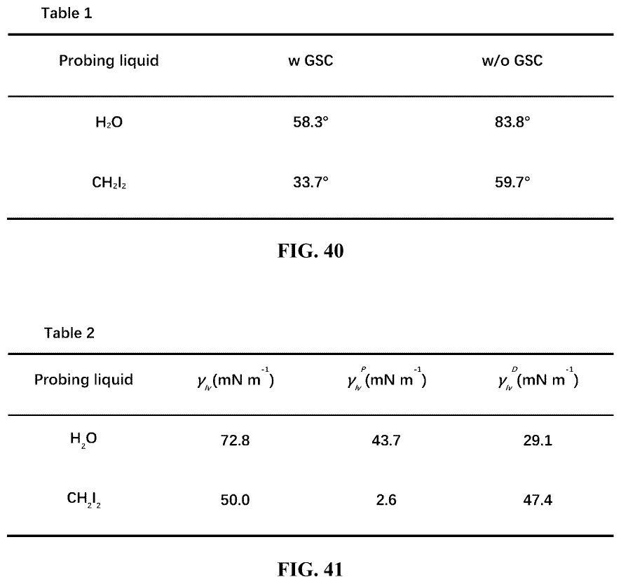

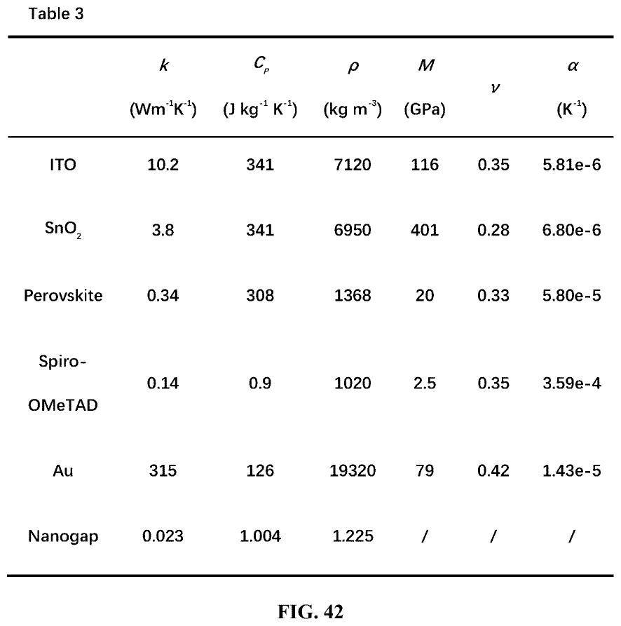

For the measurement process of the side angles of GBGs and GSCs, in the sample preparation, an epoxy glue was applied on the PMMA-protected perovskite layer and then the film was covered with a glass slide. Then, the samples are stored in a dark, dry box (RH<15%) until the epoxy was completely cured and reached its maximum bonding strength. The corresponding locations (using a glass cutter to pre-mark a grid on the glass backside of the substrate to label the SnO₂ region) were deliberately labelled to ensure the probed surfaces of SnO₂ top and perovskite bottom are from the correlated region. Similarly, a relatively smaller grid within the former was also pre-marked on the backside of the cover glass to label the perovskite region. FIG. 39 indicates that the spatial differences of AFM morphology can be considered negligible in corresponding locations. Then, a force is applied to delaminate the perovskite layer from the SnO₂ ETL. This method can effectively separate the perovskite bottom surface from the SnO₂ surface without degrading the perovskite film (in regions of sufficient area). Then, high-resolution AFM scans were performed on both SnO₂ top surface and perovskite bottom surface to acquire 2D height profiles. AFM height images were analyzed using NanoScope Analysis software (V1.8). From these images, profiles of grain boundary grooves and intragrain height were extracted. For the standardized perovskite film delamination test, samples with the structure ITO/SnO₂/perovskite/PMMA were fabricated firstly. The SnO₂ and perovskite layers were prepared as the method of PSC devices. Then PMMA solution (10 mg/mL in CB) was spin-coated at 3000 rpm for 30 seconds onto the perovskite surface, and samples were placed in a nitrogen glovebox until the solvent completely evaporated. PMMA layer was used to prevent a reaction between the epoxy resin and the perovskite layer. A blade array with 1 mm spacing was used to scribe the sample surface for fabricating a standard grid. A thin layer of epoxy film (2 μm) was applied to glue a glass substrate onto the film structure, which is kept in the dry air glovebox (<15% RH) for complete epoxy curing. The delaminated area ratio was calculated by comparing the number of perovskite grids on the peeled glass substrate to the number of total grids covered by epoxy. Rating the scale of interfacial adhesion was based on ASTM D3359 standard. 0B represented that the removed area from substrate is greater than 65%, corresponding to the poorest interfacial strength. 1B, 2B, 3B, and 4B represented the 35-65%, 15-25%, 5-15% and less than 5% removed area, respectively. 5B represented that no residual area on the substrate after delamination, corresponding to the strongest interfacial strength. For each GB and grain micro-surface, two measurements were conducted at different positions on it for the accuracy of θ and ξ.

For the thermal transport measurement, the IPVP TA experiments were performed for samples with a structure of Glass/ITO/SnO₂/Perovskite/PMMA. In IPVP TA experiments, the mid-infrared (MIR) pump pulses were produced from a high-energy MIR optical parametric amplifier (OPA; Orpheus-One-HE, Light Conversion). The OPA was powered by a Pharos amplifier with 170 fs pulse duration, 1030 nm wavelength, and 2 kHz repetition rate and reduced into 1 kHz by an optical chopper. The broadband probe pulses at a 2 kHz repetition rate were produced by a supercontinuum laser (DISCO-2-UV, Leukos), which was electronically triggered and delayed from the fs pump laser with a digital delay generator (DG645, Stanford Research Systems). The transmitted probe light was captured by a high-speed USB spectrometer (AvaSpec-ULS2048CL-EVO, Avantes). Perovskite and PMMA layers were kept about 100 nm and 30 nm thick, respectively. Samples were vibrationally excited by MIR pulses centered at 3170 nm (resonant with the N—H and C—H stretching modes), the pump-induced lattice temperature increase results in the transmittance change, which was captured by a time-delayed, broadband visible probe. Here, dT/T denotes the differential change in transmittance and is defined as dT/T=(T(t)−T(0))/T(0), where T(t) is the transmittance at delay time t after the pump excitation and T(0) is the transmittance prior to the pump excitation.

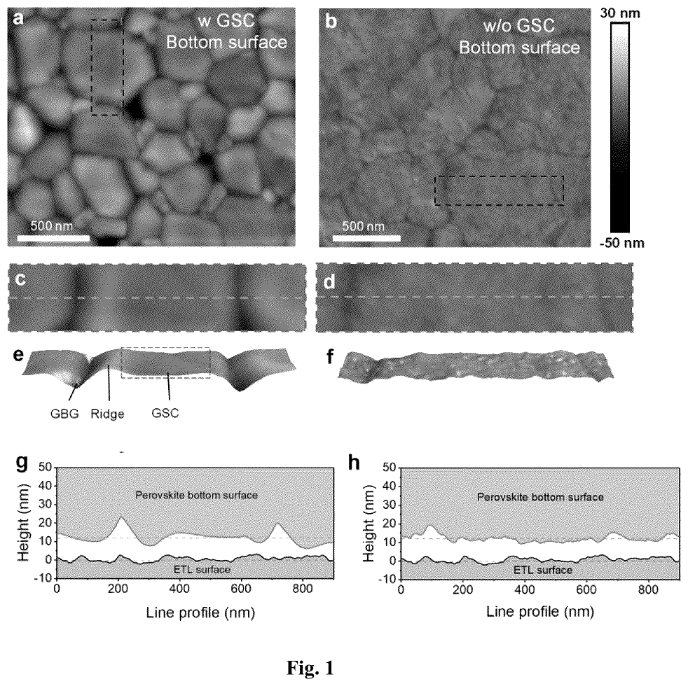

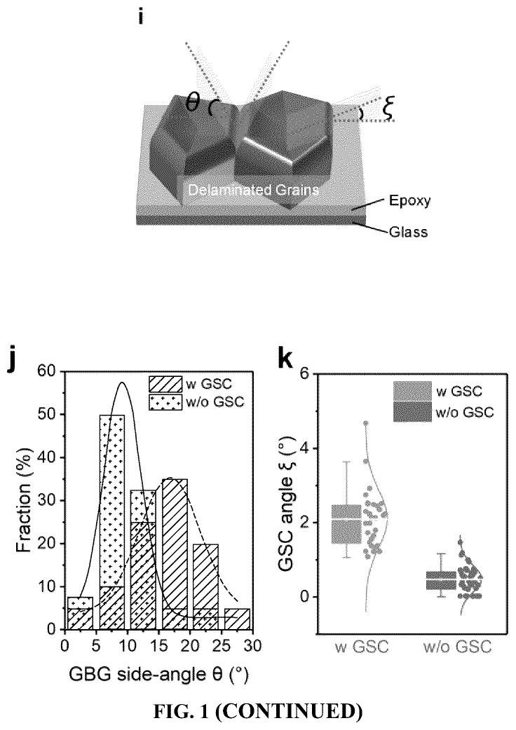

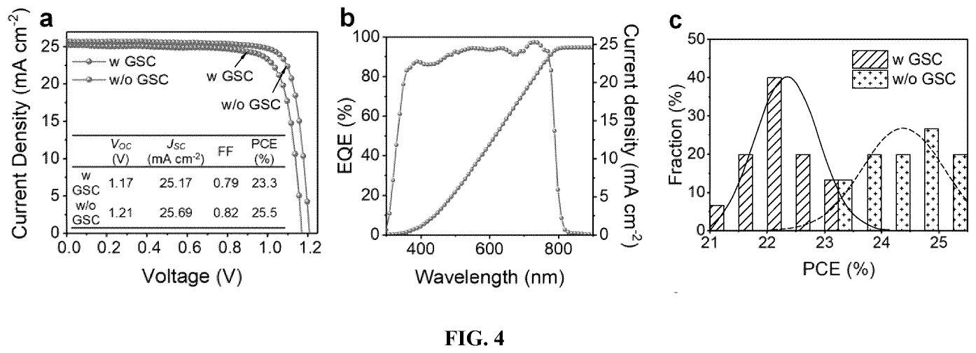

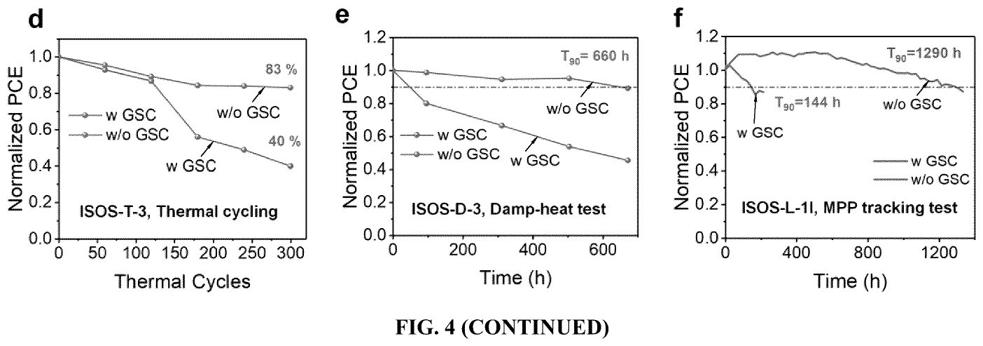

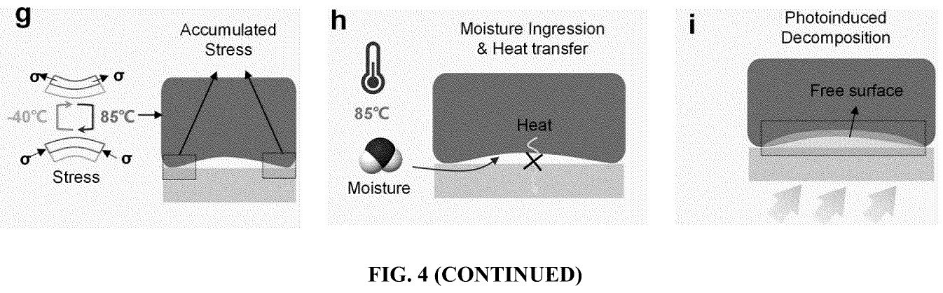

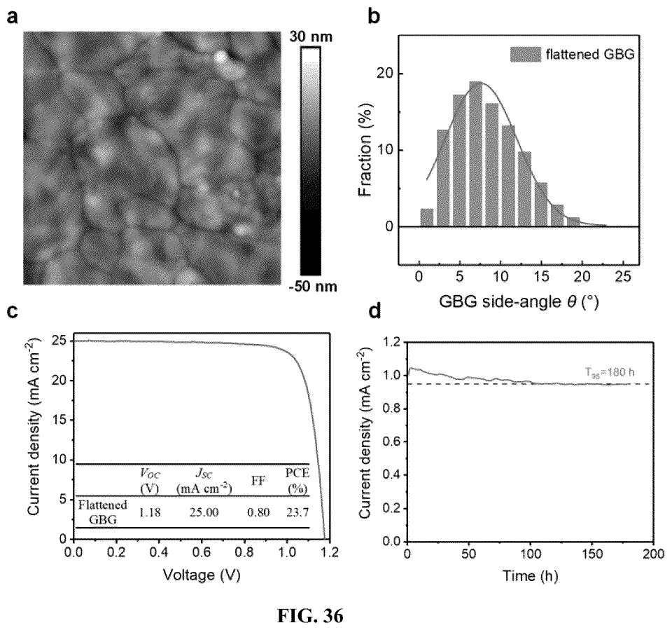

The GaussAmp function was used to fit the curves on column diagrams in FIG. 1j and FIG. 36. The normal distribution curve was used to fit the column diagrams in FIG. 4c.

### Characterization

### Geometric Characteristics and Chemical Tailoring of GSCs

Two formamidine-cerium (FA-Cs) perovskite film samples (FA_{0.9}Cs_{0.1}PbI₃ composition) were deliberately prepared with an ITO/SnO₂/perovskite structure. One (pristine film 1) was prepared from an additive-free perovskite solution while the other (target film 1) was prepared from a perovskite solution with the addition of TFSAP, an anionic surfactant. The unique molecular characteristics of TFSAP enable it to moderate microstructural evolution and to yield perovskite grains with minimum GSCs on bottom surfaces, which will be elaborated later.

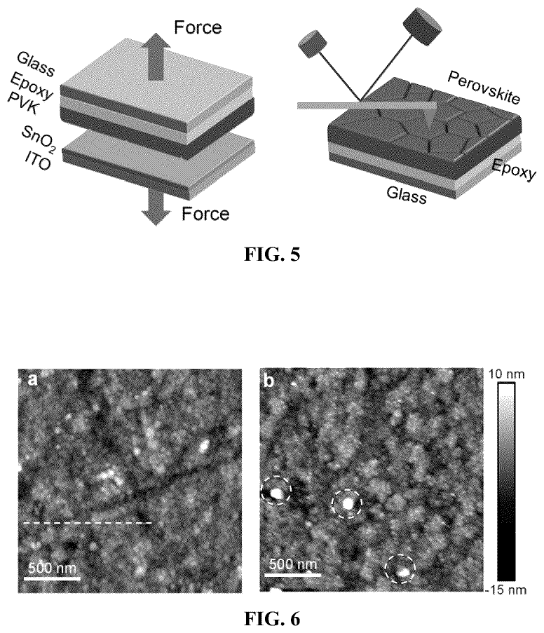

After the film fabrication, the perovskite layer was mechanically delaminated from the SnO₂ electron transport layer (ETL) using a method schematically illustrated in FIG. 5. Then high-resolution atomic force microscopy (AFM) was employed to characterize the flipped perovskite film bottom surface for quantitatively investigating the geometric characteristics of grain surface microstructures originally at the perovskite-ETL heterointerface. In FIG. 1, a-b exhibit AFM topographies of perovskite surfaces with and without GSCs, respectively. For the pristine perovskite film, a polycrystalline microstructure is observed with high-contrast GBGs formed between packed individual grains and with GSCs emerging on most grains. The GSC microstructure is distinguishable by the peripheric region higher than the central region in a specific grain in a regular film. In contrast, GSCs are rarely observable on the grain micro-surfaces of the target film. As shown in FIG. 1, the grain (c, e) contains a micro-surface with concaved centers surrounded by adjacent convex ridges and GBGs, while the grain (d, f) contains a nearly flat micro-surface. By showing a narrow slice of the AFM 2D/3D image (FIG. 1 c-f) that goes across one typical entire grain and adjacent GBs, their detailed and localized geometric characteristics were compared. For the pristine film 1, the grain contains a concaved center surface surrounded by convex ridges and GBGs, while the grains deliver nearly flat micro-surfaces for the target film 1. FIG. 1 g-h exhibit the quantitative results from the height/depth line-profiling in FIG. 1 c-d and in SnO₂ surfaces in FIG. 6a, which further attests to the minimization of GSCs as well as the flattening of GBGs once the TFSAP additive is used for the film processing. The typical surface height line-profile (guided by dashed lines in FIG. 6a) of the SnO₂ ETL top surface is also shown to demonstrate the difference in the heterointerfacial integrity. As seen, GSCs on pristine grains create obvious nanovoids in micro-interfaces while target grains provided in the present disclosure do not.

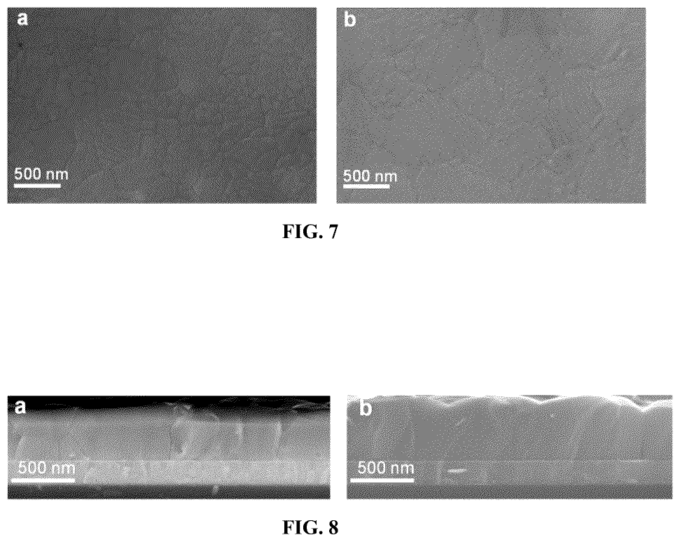

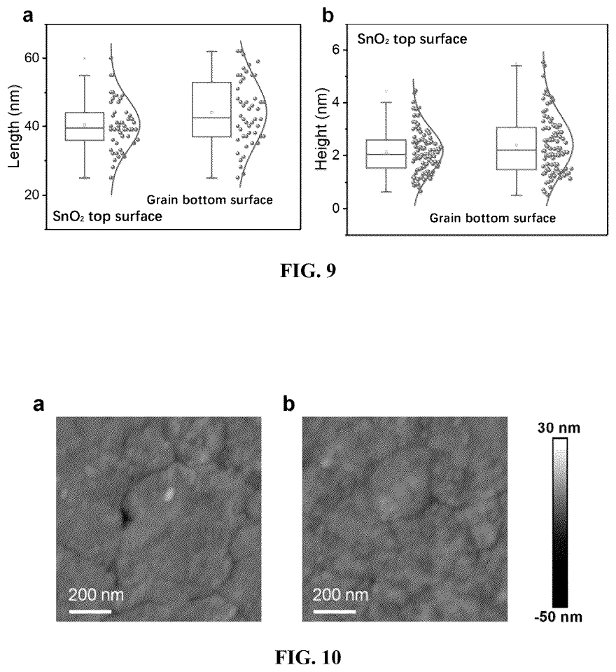

The structure of grain-CTL micro-heterointerface are elaborated as follows. AFM images of the SnO₂ top surface were obtained before and after delamination, as illustrated in FIG. 6. Because it was not practical to obtain correlated AFM images of SnO₂ ETL tops and perovskite bottoms all exactly from the same location in the film structure, a series of AFM images were acquired within a pre-labelled small area of the film, finding that the spatial differences in morphologies may be considered negligible. SnO₂ ETL top surfaces exhibit extremely low surface height fluctuations as compared with grain bottom surfaces, allowing them to be approximately treated as flat when assessing micro-heterointerface. This implies that for the pristine film cases, when perovskite grains bottom surfaces are in contact with the SnO₂ ETL top surfaces, the concaved grain center could inevitably result in nanoscale gaps, which are localized by the grain periphery. Such nanogaps exhibit relatively small depth dimensions, making them hardly observed in top-view and cross-sectional SEM images (FIGS. 7-8). In contrast, when GSCs are minimized in the target films, a high integrity in the grain-CTL micro-heterointerface is achieved. FIG. 9 illustrates even similar nanoscale morphologies of the perovskite grain bottom and SnO₂ top surface in the target film, indicating a strong structural coherence because of an intimate interfacial contact. We excluded the possibility of such morphology of the perovskite grain bottom being caused by TFSAP aggregates, as we applied an isopropanol solvent washing and observed no morphological change (FIG. 10). Note that these GSCs-induced nanovoids should be considered different from the GBGs-induced and solvent-trapping-induced voids on buried heterointerfaces earlier reported in literatures. As shown in FIG. 1e, GSCs-induced nanogap can span almost the whole grain, and it has truly statistical significance as it exists on almost every regular grain. In contrast, GBGs-induced void is only horizontally across a few tens of nanometers. The solvent-trapping-induced void is mostly a type of microscopic or macroscopic volume defect that randomly exists at the heterointerface.

To assess the microstructural tailoring effect of the surfactant of TFSAP, as schematically illustrated in FIG. 1i, a new geometric parameter is introduced herein in addition to the GBG angle θ defined previously. θ represents the angle between the tangent to the GBG side and the plane on which the perovskite compound film extends (horizontal direction). ξ represents the angle between the line connecting the apex of the convex ridge to the center of the GSC and the horizontal direction, thus roughly elaborating the degree of the curving from an ideally flat surface.

60 and 80 measurements were conducted totally to obtain the ξ and θ statistics for each film, respectively (FIG. 1 j-k). The pristine film 1 contains GSCs with an average ξ value of 2.09°. In contrast, the target film 1 exhibits significantly reduced ξ, with most values distributing within the range of 0° to 1° (0.47° on average), in which context all the grains can be considered non-concaved. It is also interesting that the GBG angle θ shows the same trend as the GSC angle ξ with the TFSAP addition. The target film exhibits flattened GBGs with an average θ value of 9.9°, decreased from 15.9° for the pristine film. These results confirm the effectiveness of the TFSAP on the microstructural tailoring of perovskite grain surface. Although the changes of GSC and GBG angles (ξ and θ) are coupled due to their inherent formation mechanisms (to be elaborated later), it is expected that the minimization of GSCs can become a crucial factor in addition of GBG flattening in constructing perovskite heterointerfaces with ideal microstructural and functional integrities, especially considering their greater original lateral dimensions.

### Analysis of the Formation and Evolution of GSCs

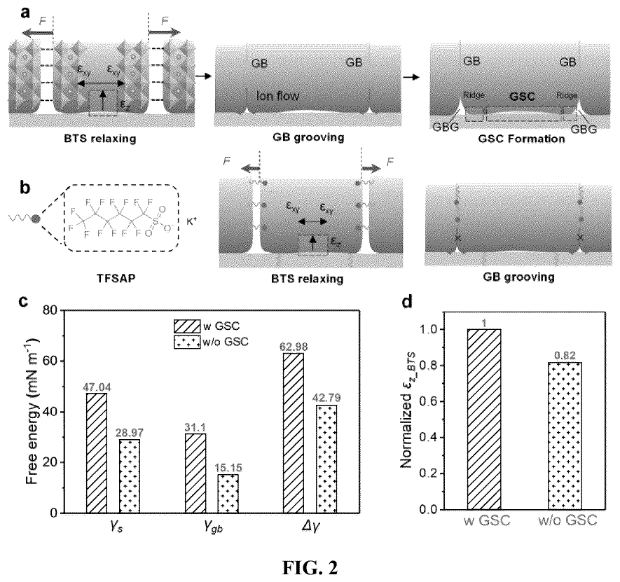

It is proposed by the inventors that the evolution of these GSCs is attributed to two main mechanistic factors, as schematically illustrated in FIG. 2a. The first factor is the intrinsic BTS generated by the grain coalescence during the solution crystallization stage. Upon the grain growth of perovskites, the side surfaces of perovskite grains will gradually approach each other. In grain coalescence, it eventually causes the bonding of adjacent grain surfaces, as illustrated using the horizontal black dashed lines between perovskite structures within grains, forming GBs. The bonding-induced biaxial interatomic force F initially induces lateral deformation ε_{xy}, thus causing an out-of-plane deformation ε_{z} (labeled using a semi-transparent box) owing to the global Poisson effect (left panel). The other is thermal-driven GB grooving during the grain coarsening stage. In grain coarsening, GB grooving is lasting, in which solid-state ion continuously diffuses from the groove to convex ridges aside (middle panel). Triggered by both processes, solid-state ion plastic flow can occur from the grain surface center and GBG regions to the convex ridges, contributing to the evolution of GSCs (right panel). GSC (labeled using a semi-transparent box) forms under these two mechanistic processes, along with the generation of convex ridges (labelled using semi-transparent boxes) (right panel). Below we elaborate on the mechanism.

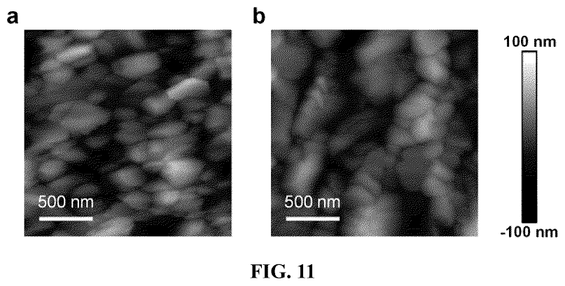

Once a perovskite grain is formed from the solution, it is expected to grow until getting in contact with adjacent grains, leading to the generation of the interatomic forces, and accordingly BTS:

$${E}_{xy \_ BTS} = {[ 4 a ( 2 {γ}_{s} - {γ}_{g b} ) \frac{1 - υ}{M} ]}^{\frac{1}{2}} \qquad ( 1 )$$

$${E}_{z \_ BTS} = U \cdot {E}_{η B T S} \qquad ( 2 )$$

where a is the half of the grain size, γₛ is surface free energy per unit area, γ_{gb} is GB energy per unit area, Mis the Young's modulus, and ν is the Poisson's ratio. This BTS will lead to the ion flow from the grain center towards the sides, accordingly generating the out-of-plane deformation (ε_{z_BTS}). Based on these, the theoretically estimated ε_{z_BTS} is at the nanometer scale, which is consistent with the experimentally measured deformation (ε_{z}) of the AFM depth profiling (FIG. 1g). The relative difference between ε_{z_BTS} and ε_{z} can be partly attributed to the contribution of the thermal-driven GB grooving which has not included yet. Once grains have coalesced, GB grooving begin to dominate GSCs formation, while the contribution to the out-of-plane deformation by GB grooving (ε_{z_grooving}) is still hard to quantify at this time. Notably, GSCs more profoundly exist on perovskite bottom surface than top surface, as the top surface is freely grown without a geometric boundary condition as we set for the bottom surface (FIG. 11).

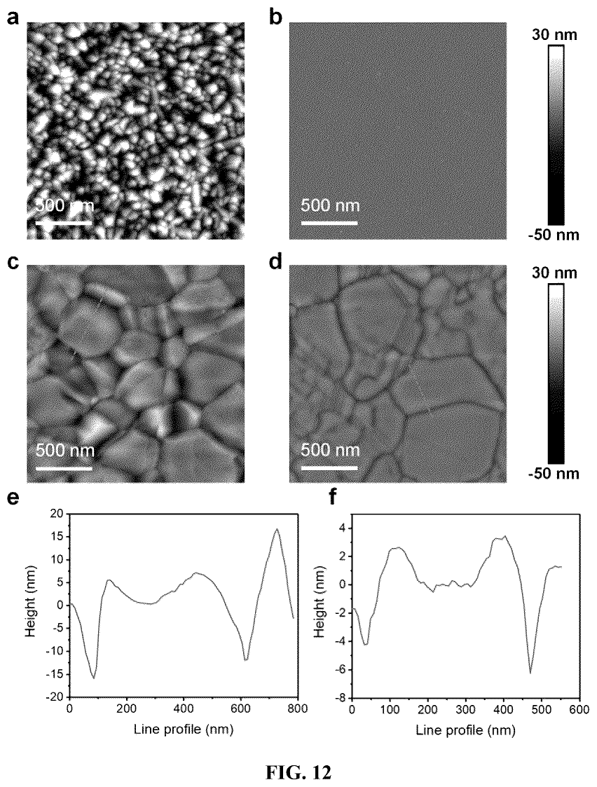

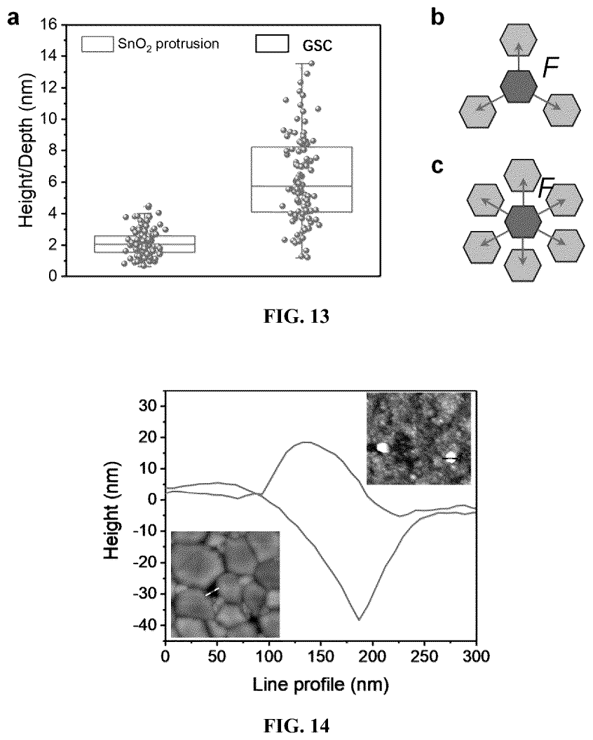

To attest the above elaborated theory coincides with our experimental observations on GSC formation, the possibilities of other potential factors dominating the GSCs formation have been excluded. First, the effect of substrate roughness was explored. FIG. 12 shows the representative AFM images of perovskite thin films fabricated on FTO and silicon wafer substrates which present much higher and lower roughness than SnO₂ ETL, respectively. GSCs are generally observed in both cases, despite a difference in the detailed geometries. Then, although there are occasional bulges on the SnO₂ ETL surface, they cannot be a major contributing factor for GSC formation, either, considering the substantial difference in the geometric characteristics between the bulges and GSCs (FIG. 13). This discrepancy raise from the different growth conditions for each grain. Some grains grow with influence of interatomic forces from less neighboring grains, resulting in the less of depths of GSCs (b), while some grains influenced by the interatomic forces from more neighboring grains, resulting in a deeper GSC (c). Third, since the perovskite bottom surfaces for AFM characterization are obtained from a mechanical peeling process, nanofragments from perovskite surface may be peeled off, which can influence the bottom surface geometry. But such nanofragments of no statistical significance are experimentally found to be mostly taken from the GBG region of the perovskite bottom surface (FIG. 14).

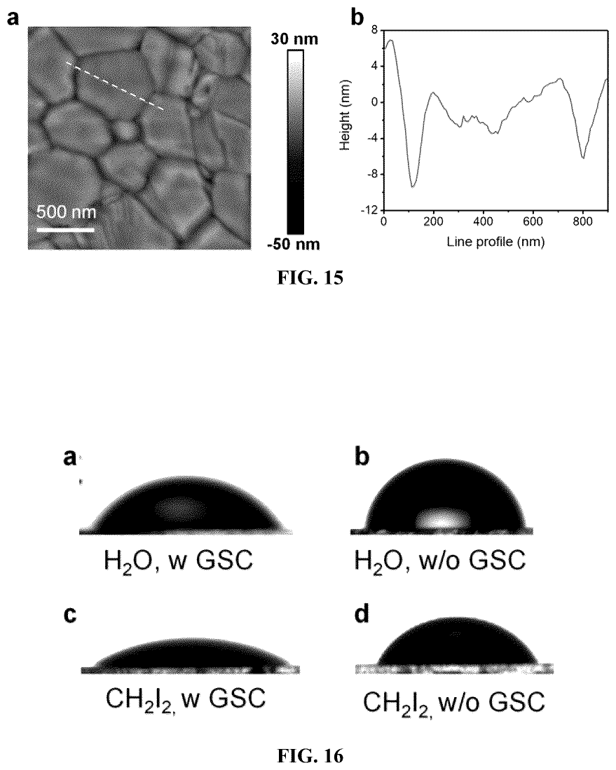

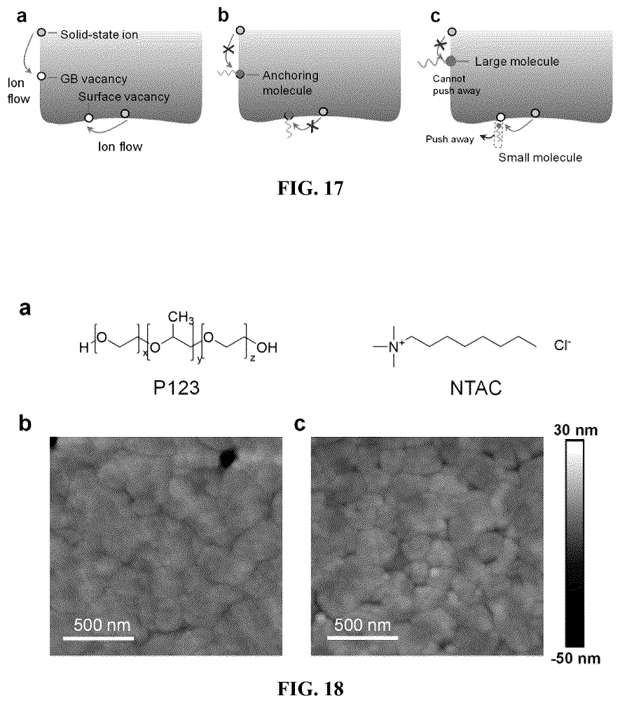

Based on the consolidated theory, as known from Equation (1), to minimize GSCs, we will need to reduce the out-of-plane deformation ε_{z_BTS} by minimizing (2γₛ−γ_{gb})^{1/2}. This rationalizes our employment of the surfactant molecule TFSAP additive to tailor the GB and surface energies. As shown in FIG. 2b (left panel), in TFSAP, the organic anion possesses two functional groups, a short all-fluorinated carbon chain and a sulfo group, and is expected to homogenously interact with perovskite surface/interface. It lowers the ε_{z_BTS} via manipulating surface energies and GB energies (middle panel) and suppresses the ion diffusion in GB grooving (right panel), thereby minimizing the formation of GSCs. Regarding the K⁺ cation, it does not impose a notable effect on microstructure and surface morphology, as supported by the AFM observations when an alternative additive of KI applied at the same concentration (FIG. 15). The organic anion of TFSAP tends to homogenously interact with the perovskite grains surfaces and GBs via the head-tail configuration (FIG. 2b middle panel), which can be attributed to two factors: (i) the polar, electron-rich sulfo group can anchor on the iodide vacancies; (ii) the all-fluorinated carbon chain contains maximum electron pairs that could effectively prevent self-aggregation. Therefore, TFSAP can reduce the surface and GB energies, as well as the difference between the two. We experimentally determined γₛ using the standard OWRK method and then γ_{gb} based on the width-depth (w-d) relationship of the Mullins' GBG model. The contact angle images with water and diiodomethane are collected in FIG. 16. The values of contact angle are listed in Table 1. The method associated with OWRK are illustrated in Other Methods. The obtained γₛ, γ_{gb} and Δγ (²γₛ−γ_{gb}) are shown in FIG. 2c, and the normalized ε_{z_BTS} are shown in FIG. 2d. As expected, there are decreases of γₛ from 0.047 to 0.029 N m⁻¹, and γ_{gb} from 0.031 to 0.015 N m⁻¹, leading to the decrease of normalized ε_{z_BTS} from 1.00 to 0.82. TFSAP, with sulfonate groups rich in electron pairs, can form coordination bonds with Pb atoms to segregate on the grain surface and GBs. Simultaneously, this chemical interaction can also inhibit the surface diffusion of solid-state ions. Since the solid-state ion flow is mainly mediated by surface/interface vacancies, as illustrated in FIG. 17, by passivating these vacancies, the ion flow may be inhibited. The inhibition effect on ion flow could be also related to the size of the molecules, as a larger molecule can serve as a kinetically more stable barrier for the solid-state ion flow. Therefore, the solid-state ion flow in the GB grooving process can be greatly alleviated (FIG. 2b right panel). These results well support our proposed mechanism for GSC microstructural evolution and elucidate the role of TFSAP.

Two other surfactant molecules Pluronic® P-123 (P-123) and N,N,N-trimethyloctan-1-aminium chloride (NTAC) were also used in addition to TFSAP, and achieved similar effects on the grain micro-surface (FIG. 18). Specifically, the —OH groups at the two tails of Pluronic® P123 can form relatively weak hydrogen bonds with organic FA⁺ cations in perovskite, while the quaternary ammonium cations of NTAC can interact with iodide ions in perovskite. These interacting surface molecules tailor the interfacial energies to relax BTS and hinder ion flow, thus leading to the GSC elimination. Therefore, our proposed mechanism applies to the P123 and NTAC cases, regardless of their distinct molecular structures and different interaction modes with perovskite grains. These reflect that our GSC approach can be generic and there is space for future optimization.

### GSC Effects on Hetero-Interfacial Properties

### 1. The Optoelectronic and Chemical Properties of the Perovskite-CTL Heterointerfaces

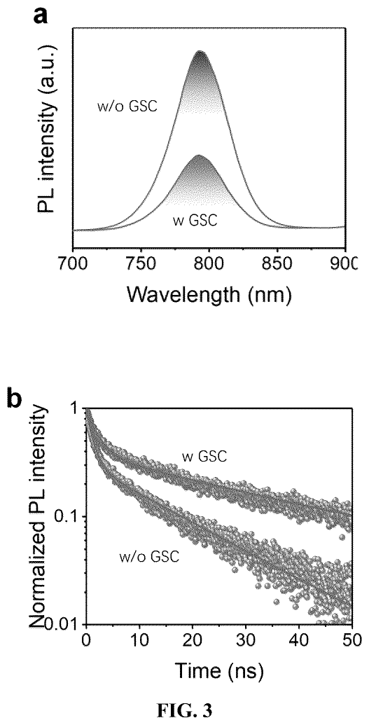

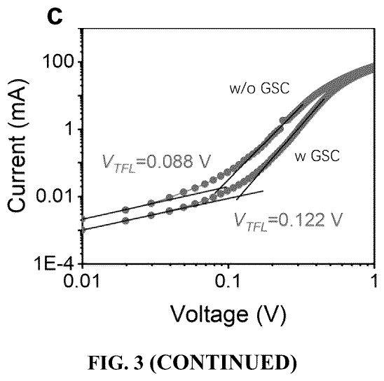

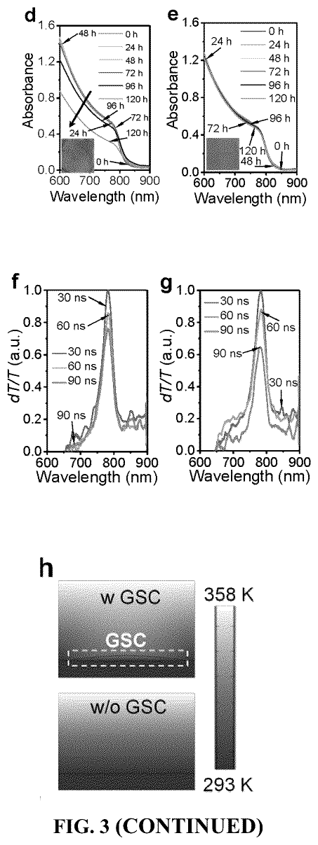

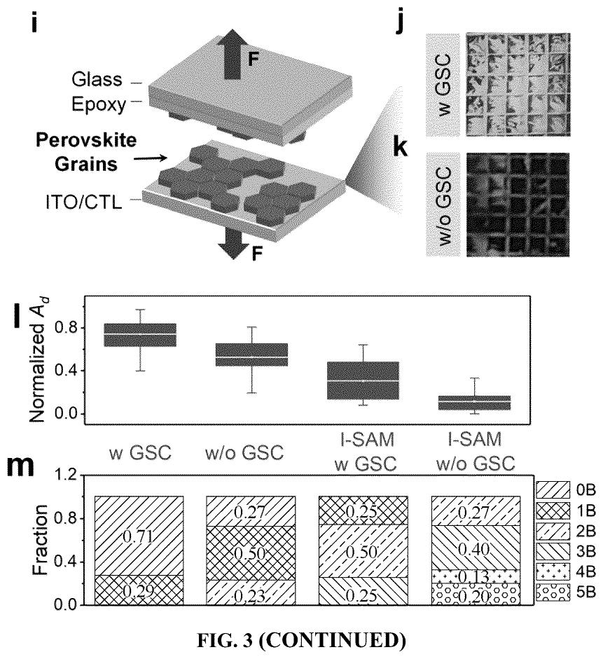

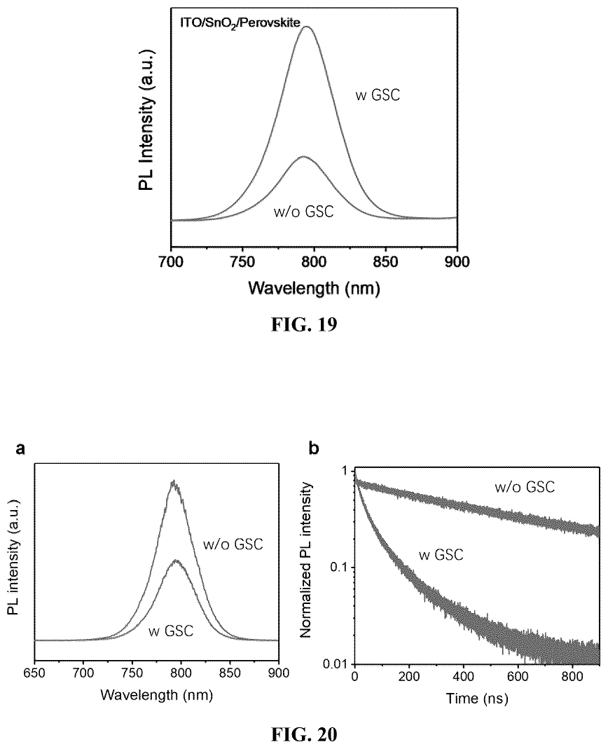

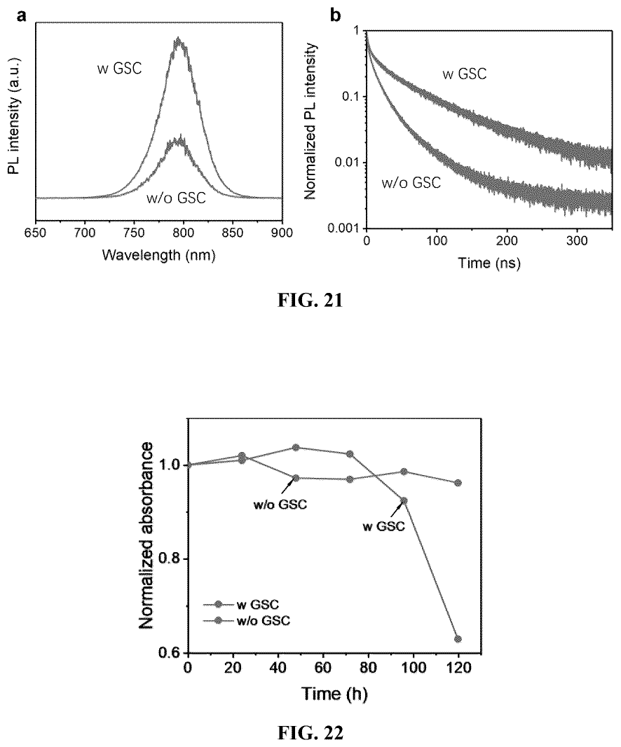

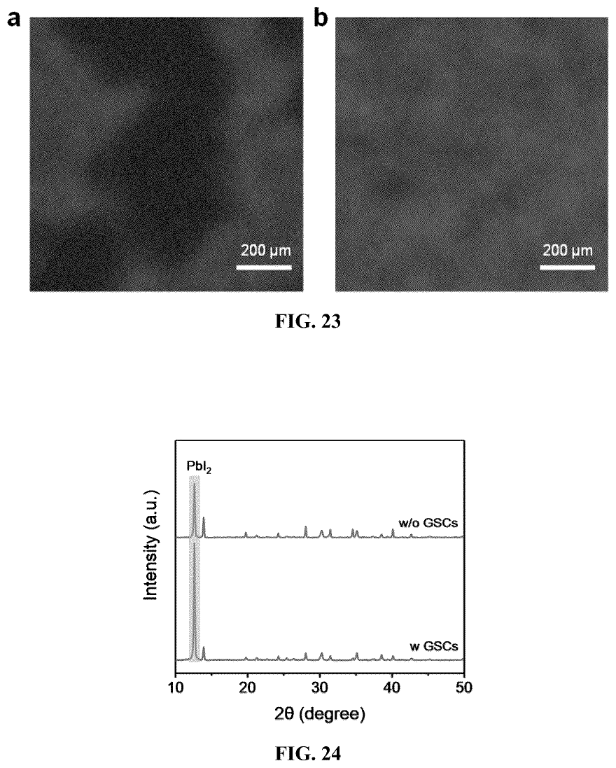

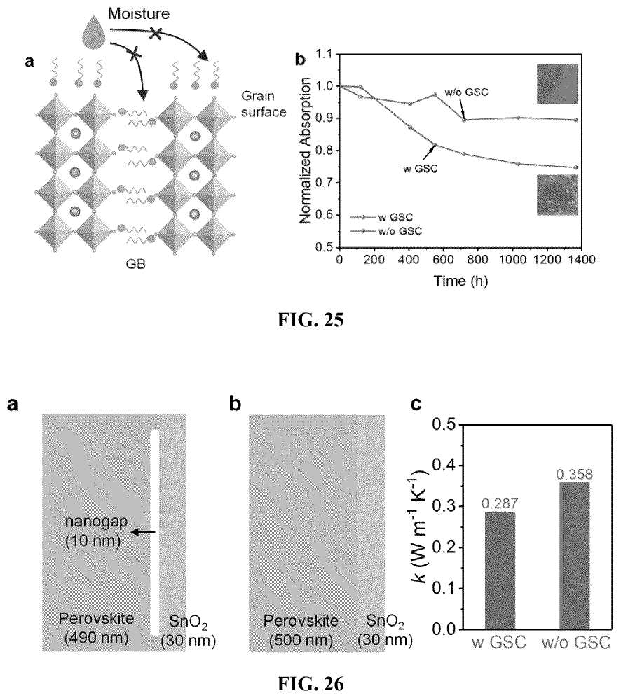

The optoelectronic and chemical properties of the perovskite-CTL heterointerfaces were assessed before and after the GSC engineering. The steady-state photoluminescence (PL) spectra of both perovskite films on quartz substrates are shown in FIG. 3a, which indicate significantly reduced nonradiative recombination in the presence of GSCs, attributing to the physical passivation effect on free surfaces in GSCs to reduce trap densities. FIG. 3b shows the time-resolved photoluminescence (TRPL) spectra for both films with and without GSCs deposited on SnO₂-ETL-coated ITO. It is found that the average PL lifetime (τ_{avg}) decreases from 32.7 to 14.8 ns in the absence of GSCs, suggesting the electron-extracting properties of the perovskite heterointerface are strongly enhanced. The steady-state PL measurements based on the ITO/SnO₂ ETL/perovskite sample structures also show consistent results (FIG. 19). To quantitatively measure the trap density, space-charge-limited current (SCLC) measurements were performed on both perovskite films, as shown in FIG. 3c. The value of trap-filled-voltage (V_{TFL}) decreases from 0.122 to 0.088 V, corresponding to a decrease of trap density from 1.499×10¹⁴ to 1.082×10¹⁴ cm⁻³ after the GSC engineering. PL measurements were conducted on flipped, delaminated perovskite films, as shown in FIG. 20. For the target film, the peak intensity of the steady-state PL spectrum is higher. The photocarrier lifetime (578 ns) fit from the TRPL spectrum is also longer than that for the pristine film (99 ns). Both suggests a lower intensity of trap states on the bottom surface of the target film. PL spectra were further measured from the bottom sides of both pristine and target films deposited on SnO₂ ETL coated quartz substrates. A more effective PL quenching was observed in the target film (FIG. 21). FIG. 3d-e show the comparison of the optical absorption spectra of both perovskite films with and without GSCs under accelerated aging tests (3-sun-intensity, and 80° C.). According to the normalized absorbance variations at the wavelength of 700 nm for both films (FIG. 22), the target film shows only a marginal decrease in absorbance and the film color remained black, while the pristine film degraded quickly. This is consistent with our hypothesis that the GSC-induced nanovoids can serve as initial degradation sites since a free bottom surface tends to suffer more severely from photothermal and environmental stresses, which aligns with that of inter-grain nanovoids in earlier studies. PL mapping images and X-ray diffraction (XRD) patterns in FIGS. 23-24 also attest to the enhanced chemical stability after the GSC engineering. There could be also a positive contribution of the TFSAP chemical functionalization on these properties, e.g. moisture tolerance (FIG. 25), which can be considered in addition to the effects of transformed grain micro-surfaces.

### 2. The Crucial Thermomechanical Properties of the Perovskite-CTL Heterointerfaces.

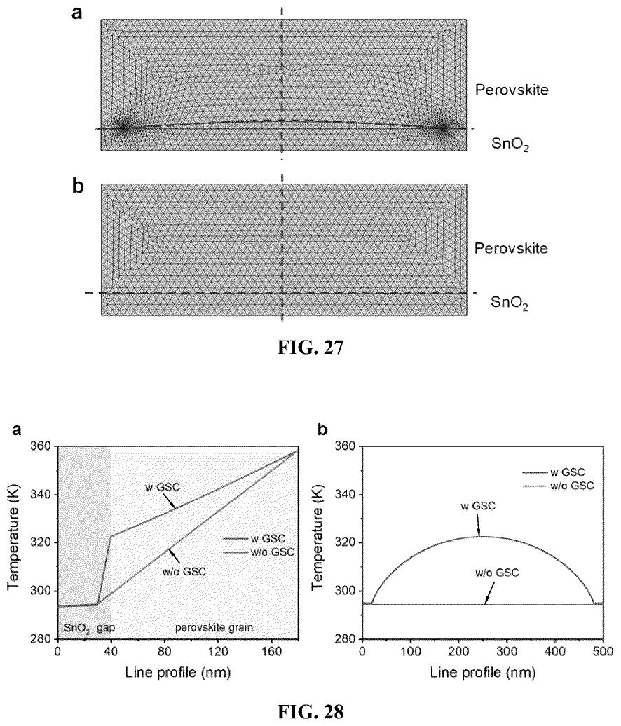

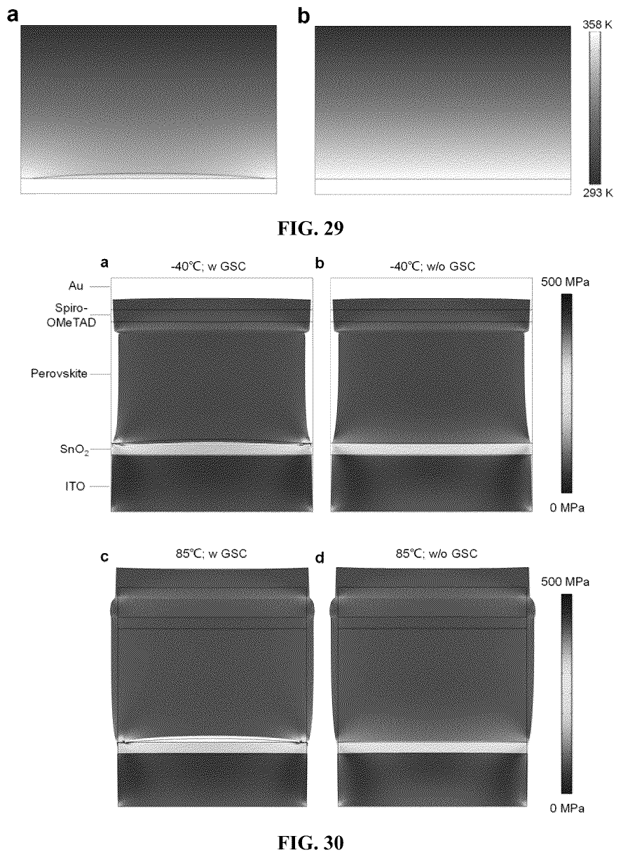

Infrared-pump visible-probe (IPVP) transient absorption (TA) experiments were performed to assess the heat-transfer dynamics of heterointerfaces with and without GSCs, with associated details illustrated in Other Methods. The differential change in transmittance (dT/T) can assess the heat-transport ability. FIG. 3 f-g show the variation of dT/T under different delay time. The heterointerface without GSCs exhibit an enhanced decrease as compare with pristine samples, corresponding to faster heterointerfacial heat-transfer. It reveals that GSC-induced nanovoids hinder heat-transfer in heterointerfaces. FIG. 26 illustrates the constructed micro-interfacial models for calculating thermal conductivity k, where nanogap is simplified as a rectangle air gap. The overall k increases from 0.287 with GSCs to 0.358 W m⁻¹ K⁻¹ in the absence of GSCs, supporting the results obtained in IPVP TA experiments. Finite element analysis (FEA) based on the models in FIG. 27 was further employed, and the 2D temperature distribution is shown in FIG. 3h and temperature-line profiles are shown in FIG. 28 with a case of internal thermal source. The strongly increased temperature and the inhomogeneous transverse distribution are observed in the nanogap region, proving that GSCs not only act as an interfacial thermal resistance for vertical interfacial heat transfer but also induce non-uniform temperature distributions at the grain bottom. The temperature distribution as a case of an external thermal source delivers the same conclusion, as shown in FIG. 29. As a result of these effects, heat accumulation is expected in the pristine perovskite film, potentially leading to thermochemical and thermomechanical issues during the device durability tests, under two kinds of thermal gradients of internal and external heat sources. In addition, FIG. 30 reveals the thermal stress accumulation at the junction point under the deformation of micro-heterointerface with GSCs at −40° C. and 85° C., which is the other stressors to break the mechanically grain-CTL connection under severe temperatures in the thermal cycling test.

### 3. The Mechanical Reliability at the Perovskite-CTL Heterointerface

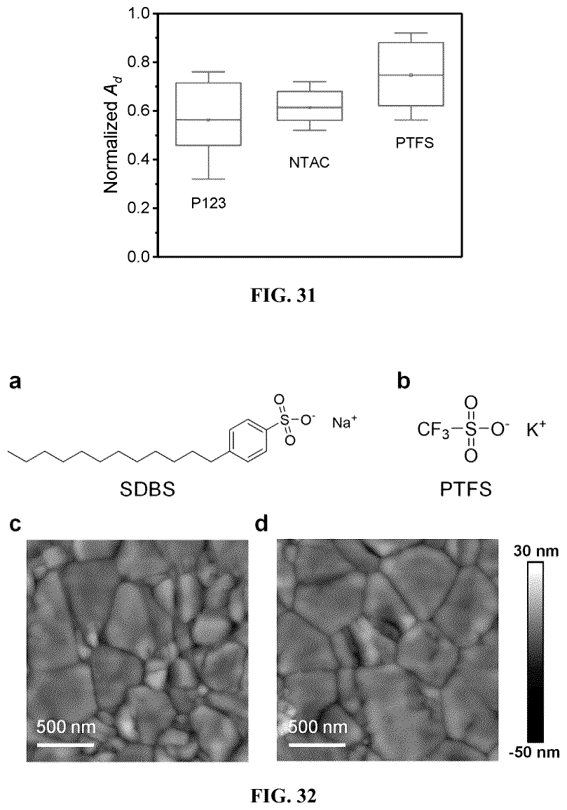

For assessing the mechanical reliability at the perovskite-CTL heterointerface, a tape test based on the ASTM D3359 standard was employed. This international standard is widely used to assess the adhesion reliability of a film to a substrate. The experimental process is schematically illustrated in FIG. 3i. Here, standard perovskite grids (1×1 mm²) were manually prefabricated onto the film by blades. Then the glass substrate with epoxy at the corners was used as the tape to delaminate perovskite grids from the SnO₂ CTL surface. The normalized delaminated area can qualitatively reflect the mechanical adhesion strength of the perovskite grains onto the SnO₂-ETL-coated ITO. FIG. 3j-k are photographs of residual perovskite grids (on SnO₂-ETL-coated ITO) for the pristine and target cases, which clearly reflect the stronger film adhesion in the absence of GSCs. The statistical distributions of normalized delaminated areas for both perovskite films are shown in FIG. 3k. The GSC engineering decreases the mean values of normalized delaminated areas from 0.740 to 0.524. The enhancement in overall film mechanical reliability may be attributed to the accumulation of individual micro-heterointerfaces where grains have been in full contact with the SnO₂ ETL. While herein the chemical interaction of TFSAP with perovskite and SnO₂ may contribute to the improved adhesion strength, it is not considered as a dominating factor. To support this, P123 and NTAC were further employed as the processing additive which led to a similar elimination of GSCs, but these additives are not expected to exhibit very profound chemical interaction with either SnO₂ or perovskite. Nevertheless, a similar level of improvement in interfacial adhesion strength to that caused by TFSAP is observed (FIG. 31).

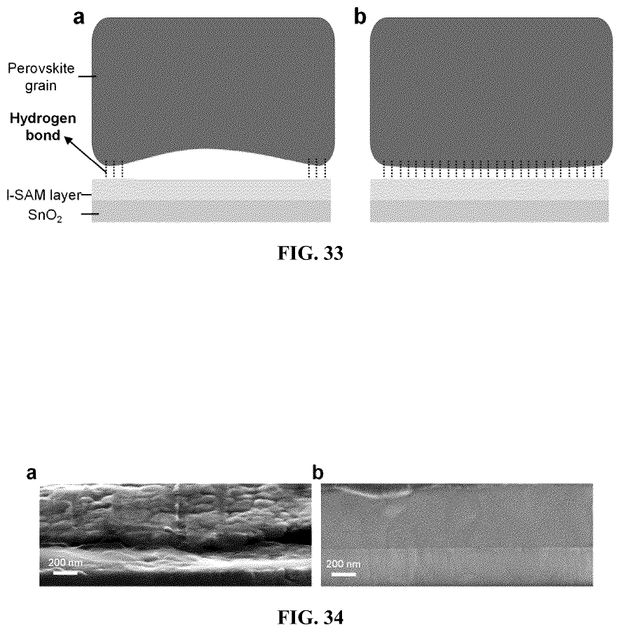

In the meanwhile, for the case of potassium trifluoromethanesulfonate (PTFS) containing the same functional group as TFSAP while cannot flattening GSCs (FIG. 32), a notable improvement in the adhesion strength was not observed (FIG. 31). The benefit of the non-concaved grains can be further amplified when an interfacial molecular glue is used, which in turn attests to the microstructural effects. A reported interfacial glue of iodine-terminated self-assembled monolayer (I-SAM), (3-iodopropyl)trimethoxysilane (Si(OCH₃)₃(CH₂)₃I) between perovskite grains and ETL was tested. As shown in FIG. 3 l, with the I-SAM, the target film can demonstrate a further boosted interfacial adhesion, with the mean value decreasing from 0.291 to 0.118. It can be observed that I-SAM deposition on SnO₂ ETL surface can have a more profound contribution to the interfacial reliability enhancement, as compared to GSC minimization solely. Nevertheless, as GSC minimization increases the interfacial contact area, it further facilitates the formation of more effective interfacial hydrogen bonds via I-SAM incorporation. To provide a more intuitive illustration, the delamination experiment results according to the ASTM D3359 standard were grouped to rate the adhesion, ranging from scale 0B to scale 5B, where 0B represents the worst while 5B represents the best adhesion strength, as shown in FIG. 3 m. The distribution of 0B-5B matches the results FIG. 3 l, where target group without GSCs overall obtained a better adhesion scale. It is expected that the flat grains create more molecular bonds in the grain centers, thus demonstrating interfacial adhesion, as shown in FIG. 33. These results show that minimizing GSCs not only enhances the mechanical reliability on perovskite-CTL heterointerface but also imposes an additional positive effect on the established SAM-based interfacial engineering.

### GSC Effects on PSC Device Performance and Durability

### 1. Photovoltaic Performances of PSC

The effects of minimized GSCs on device photovoltaic and durability performances was evaluated, with the conventional device structure of ITO/SnO₂ ETL/Perovskite film/Spiro-OMeTAD/Au. FIG. 4a shows the current density-voltage (J-V) curves of the champion PSC devices at reverse scan for both pristine and target films. To explore the efficiency potential, minimizing GSCs at grain-CTL heterointerfaces has significantly improved the optoelectronic performance of devices, leading to a PCE of 25.5% with an open-circuit voltage (V_{OC}) of 1.21V, a short-circuit current density (J_{SC}) of 25.69 mA cm⁻², and a fill factor (FF) of 0.82. The external quantum efficiency (EQE) spectrum of this PSC device with an integrated J_{SC} of 24.60 mA cm⁻² is shown in FIG. 4b, demonstrating a consistent integrated current density. For comparison, the champion PSC made with the pristine film shows a PCE of 23.3% with a V_{OC} of 1.17 V, a J_{SC} of 25.17 mA cm⁻², and an FF of 0.79. FIG. 4c shows the PCEs statistical distributions of devices with and without GSCs. The significant improvement of V_{OC} and FF can be explained by the boosted electron-extraction and reduced non-radiative recombination in perovskite films without GSCs (FIG. 3a-c). This improvement can be attributed mainly to the improved functional integrity of micro-heterointerfaces owing to GSCs minimization.

### 2. PSC Durability Under Different External Stressors

Then the PSC durability results were obtained under different external stressors following international standard protocols, as shown in FIG. 4d-f. It is considered that Spiro-OMeTAD hole-transporting layers (HTLs) has uncertain influence on the device durability results although using it is suitable for demonstrating the efficiency potential. Therefore, the PSC devices for these durability tests adopt PTAA.

First, the PCE variations of PSCs were monitored under thermal fatigue stressors. The thermal-cycling test was performed in a program-controlled environmental chamber, following the ISOS-T-3 protocol that entails thermal cycles from −40° C. to 85° C. For the PSC without GSCs, typically, 83% of the initial PCE is retained after 300 temperature cycles (FIG. 4d), largely outperforming that (40%) of the regular PSC. Note that the initial PCEs of devices with and without GSCs in the ISOS-T-3 tests are typically 19.9% and 21.0%, respectively. FIG. 4g illustrates the periodic compressive-tensile strain (FIG. 30) caused by the difference in thermal expansion coefficients on the perovskite heterointerface during the thermal cycling test. Unlike the case of non-concaved grains, GSCs locally break the structural integrity of micro-heterointerfaces and leave nanovoids contained at the grain-CTL micro-heterointerface, leading to only mechanically weak grain ridge-based connections as shown in the right panel. This weak connection can easily cause delamination under interfacial fatigue because of the abnormal increase of interfacial stress in micro-interfaces with GSCs (FIG. 30). FIG. 34 confirms that severe grain degradation and interfacial delamination have occurred after 300 thermal cycles for the pristine case, whereas for the non-concaved case, the high-integrity of the grain-CTL micro-heterointerface is retained. Then, it is expected that the existence of these GSCs-induced nanovoids can accommodate the moisture and hinder the heat transfer at the micro-interface in the damp-heat test, as illustrated in the inset of FIG. 4h. GSCs can effectively facilitate the moisture ingression and hinder the grain-CTL heat transfer, resulting in moisture and heat accumulation at the micro-heterointerface. The device durability was evaluated under damp-heat conditions (85° C., 85% RH) following the ISOS-D-3 protocol. Typically, PSCs without GSCs can maintain 90% of their initial efficiency after 660 h testing (FIG. 4e), and the regular PSC shows only 45%. Note that the initial PCEs of devices with and without GSCs are typically 20.3% and 21.5% in the ISOS-D-3 tests respectively. The elimination of nanovoids in buried heterointerface (as natural hosts for moisture molecules), together with the homogenous distribution of TFSAP on interfaces with hydrophobic fluorocarbon chains, contributes to the better humidity durability in target devices (FIG. 25). The homogeneous lateral temperature distribution and facilitated grain-SnO₂ heat transfer also promote better high-temperature durability in target devices (FIG. 3f-h). Furthermore, maximum power point (MPP) tracking tests were performed following the ISOS-L-11 protocol. Typically, upon MPP operation for 1290 h, the PSC without GSCs still maintains 90% of the initial PCE (FIG. 4f), whereas the regular device stands for only 144 h before the initial PCE drops to 90%. Note that the initial PCEs of devices with and without GSCs are typically 20.5% and 21.4% in the ISOS-L-11 tests respectively. Since GSCs introduce more free micro-surfaces which are not physically passivated by the SnO₂ ETL, it is not surprising that GSCs can serve as facile sites where the loss of stoichiometry can occur at the illustration side (FIG. 4i inset), as demonstrated by the better rigorous photothermal stability of perovskite films without GSCs (FIG. 3d-e). In addition, excess photogenerated carriers localized at GSCs could not be effectively extracted by SnO₂ ETL (FIG. 3b), which can induce charge accumulation and accelerate the perovskite degradation via enhanced ion activities. The combination of excellent thermal cycling, damp-heat, and MPP tracking stabilities are comparable to the best in the literature.

Finally, confirming the positive effects of GSCs minimization requires excluding the possible contributions from surfactant's chemical passivation and GBGs flattening. In this regard, it is observed that there is strong consistency between the varying trend of the GSC angles and device PCEs by optimizing the TFSAP addition amount. The optimized concentration of TFSAP can be 0.3-0.9 mg/ml in the perovskite precursor solution.

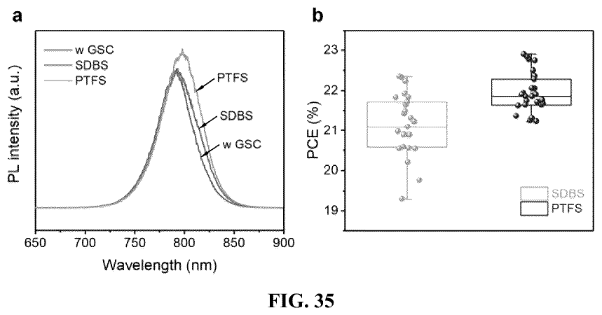

Also, when sodium dodecyl benzene sulfonate (SDBS; a classic surfactant molecule with sulfonate group) and PTFS (shorter carbon fluorine chain than TFSAP) were added, limited effects of these two molecules in altering the GSC geometry was observed when the same additive concentration is applied as TFSAP, as shown in FIG. 32. While these two are expected to exhibit similar chemical passivation effects at the molecule scale like TFSAP, under the specific experimental conditions, we did not observe any notable increase in the PL intensity and device PCEs (FIG. 35). Therefore, it can be deduced that the contribution of TFSAP to the device improvement is primarily from the observed GSC geometry optimization rather than its possible chemical passivation effects. Furthermore, the perovskite films with GBGs flattened to a similar angle θ were fabricated using a previous reported method. The AFM images of perovskite bottom surface and statistical distribution of GBG angle θ are shown in FIG. 36. The J-V performance and device stability demonstrate a lower level of improvement as compared to the approach used in this work, dictating the nontrivial role of GSCs minimization on the overall device improvements.

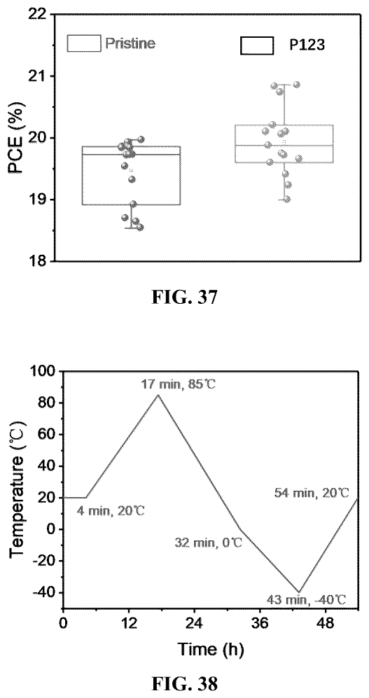

While an effective GSC elimination is found to contribute to the enhancement in device performance, there could also be other potentially affects. Taking the P123 case as an example, to induce the GSC elimination, a relatively high additive concentration is used, which creates insulating surface and thus lead to an only limited PCE increase (FIG. 37).

In summary, the present disclosure revealed a previously overlooked microstructure, GSC, and elucidated its microstructural evolution process, along with its detrimental effects on the structural integrity, charge-extracting, chemical stability, and thermomechanical reliability of the buried perovskite grain-CTL heterointerfaces. Through using the surfactant molecules (such as TFSAP) to minimize GSCs, a robust perovskite heterointerface was successfully constructed in PSCs, consisting near-ideal micro-heterointerface segments. The resultant PSC not only delivers an improved PCE of 25.5% but also retains its initial efficiencies of 83%, 90%, and 90% after undergoing 300 thermal cycles (ISOS-T-3 protocol), 660 h of damp-heat exposure (ISOS-D-3 protocol), and 1290 h of MPP operation (ISOS-L-11 protocol), respectively. The present disclosure highlights a crucial but neglected perovskite surface microstructure type, and its nontrivial effects on the performance and durability of PSCs. The insights into the microscopic structure-property-performance relationship gained from this work can add to the established understandings and contribute to the broad efforts developing highly efficient and stable PSCs and other optoelectronic devices.

### Other Methods

OWRK method. In the OWRK method, according to the balance of forces at the three-phase contact point where air, liquid, and solid meet, Young's equation is written as

$${γ}_{s v} = {γ}_{s l} + {γ}_{l v} cos θ \qquad ( 1 )$$

where γₛᵥ is the surface free energy of the solid, γₛₗ is the interfacial tension between the liquid and solid, γₗᵥ is the surface tension and θ is the contact angle. The adhesion work is defined as:

$${W}_{a} = {γ}_{s v} + {γ}_{l v} - {γ}_{s l} = {γ}_{l v} ( 1 + cos θ ) \qquad ( 2 )$$

The combining rule proposed by the OWRK model is indicated below:

$${W}_{a} = 2 ( \sqrt{{γ}_{s v}^{D} {γ}_{lv}^{D}} + \sqrt{{γ}_{s v}^{P} {γ}_{lv}^{P}} ) \qquad ( 3 )$$

where

$${γ}_{s v}^{D} and {γ}_{lv}^{D}$$

are dispersive components,

$${γ}_{s v}^{D} and {γ}_{lv}^{D}$$

and are polar components of solid and liquid surface energies, respectively. Combined with Young's equation, we get

$${γ}_{lv} ( 1 + cos θ ) = 2 ( \sqrt{{γ}_{sv}^{D} {γ}_{lv}^{D}} + \sqrt{{γ}_{sv}^{P} {γ}_{lv}^{P}} ) \qquad ( 4 )$$

There are two unknown parameters

$${γ}_{s v}^{D} and {γ}_{lv}^{D}$$

if the dispersive components and polar components of the probing liquid are known. Based on that, H₂O and diiodomethane with known dispersive and polar parts of surface tensions are selected to compute the solid surface free energy, with their parameters listed in Table 2.

Mullins GBG model. The Mullins GBG model was utilized to determine the GB energy γ_{gb}, which can be calculated by the equation:

$$\frac{{γ}_{gb}}{{γ}_{s}} = 2 sin ( {tan}^{- 1} ( \frac{m d}{2 w} ) ) \qquad ( 1 )$$

where m is typically a constant equal to 4.73, w is the GBG width, and d is the GBG depth. Surface energy γₛ has been determined by the OWRK method. The depth and width values were measured using NanoScope Analysis software (V1.8). A total of 40 times measurements for the groove width and depth and the mean value of them was utilized to determine the value of γ_{gb} in FIG. 3c.

GSC microstructure evolution induced by BTS. We propose a quantitative physical model to deduce the GSC formation process by BTS and explore the role of TFSAP on flattening GSCs.²⁸ This model offers a simplification by representing perovskite crystallites as a perfectly regular array of hexagonal crystallites to simulate the grain coalescence process. The size of each hexagonal crystallite is 2a, with a height of h. The out-of-plane separation between adjacent crystallites is denoted as Δ. Let γ₁ represent the surface energy of the crystallite, γ₂ represent the grain boundary energy, M represents the Young's modulus, and ν represent the Poisson's ratio. The free energy per unit film area of each crystallite before coalescence E₁ can be expressed as

$${E}_{1} = {E}_{0} + \frac{2 h {γ}_{1}}{a} \qquad ( 1 )$$

where E₀ represents the free energy per unit area regarding the upper and lower surfaces, while the second term denotes the free energy per unit area of the side surfaces. When crystallites coalesce, each crystallite is applied a biaxial elastic strain to fill the gaps, resulting in an out-of-plane strain of ε=Δ_{xy}/2a. In this process, two side surfaces will be consumed to form a new grain boundary. The free energy per unit film area of each crystallite before coalescence E₂ can be expressed as

$${E}_{2} = {E}_{0} + \frac{h {γ}_{2}}{a} + \frac{M}{1 - υ} {h ( \frac{{Δ}_{xy}}{2 a} )}^{2} \qquad ( 2 )$$

where the second term represents grain boundary free energy per unit area and the third term denotes the strain energy per unit area. M/(1−ν) represents the biaxial modulus of the crystallites. Here, we did not consider the anisotropy of crystallites and the constraints from the substrate. When E₂<E₁, the grain coalescence process is spontaneous. When E₂=E₁, the maximum out-of-plane deformation Δₘₐₓ can be calculated, and we can determine the maximum biaxial tensile stress σₘₐₓ:

$${Δ}_{max} = {[ 4 a ( 2 {γ}_{s} - {γ}_{gb} ) \frac{1 - υ}{M} ]}^{1 / 2} \qquad ( 3 )$$

$${σ}_{max} = \frac{M}{1 - υ} \frac{{Δ}_{max}}{2 a} = {( \frac{M}{1 - υ} \frac{2 {γ}_{s} - {γ}_{gb}}{a} )}^{\frac{1}{2}} \qquad ( 4 )$$

where γₛ and γ_{gb} are the surface energy and GB energy per unit area, respectively. The biaxial tensile stress can be very high even for small grains. Considering the less Young's Module during thermal-induced coalescence, and the existence of ion plastic flow at grain surfaces, we speculated that surface deformation occurs via biaxial ion plastic flow for relaxing this high stress, finally leaving concaves at the grain surface.

Note that the elaborated theory above is only applicable to the standard case of each grain containing only one GSC, which is suitable for analyzing the perovskite film with a standard thickness (˜300 nm) as in our work. In practice, we experimentally observed that when the film thickness is beyond the standard thickness, it becomes evident that one grain can contain multiple GSCs, calling for the need of modifying the theory for further illustrating the GSCs formation.

### Multiscale FEA Simulation

The simulation of the micro-heterointerface was conducted using the finite element analysis. The thermomechanical parameters of materials were collected in Table 3.

For the simulation of heat transfer at the micro-interface, only perovskite and adjacent SnO₂ layer were induced. The scale of the perovskite and SnO₂ layers were set at 500×300 nm² and 500×30 nm², respectively. GSCs were modeled by adding a crescent-shaped air gap with a length of 460 nm and a depth of 10 nm at the interface. In the case of internal thermal sources, the middle region of perovskite film needed to be a thermal source with a constant high temperature. Therefore, the height of the perovskite grain was reset to 150 nm, and the top boundary (corresponding to the middle region) was set to be a high temperature. In the models with and without GSC, we divided the geometry into 3464 and 2324 triangular elements, respectively. In the solid heat transfer simulation, interfacial thermal resistance was not considered. Boundaries without an initial temperature set was considered thermally insulated.

For the thermal stress and solid elastic deformation simulation, Au (80 nm), Spiro-OMeTAD (30 nm), perovskite (300 nm), SnO₂ (30 nm), and ITO (140 nm) layers were all constructed to take the device integrity into consideration. GSCs were modeled as the same as the heat transfer simulation. In the models with and without GSC, we divided the geometry into 2564 and 1704 triangular elements, respectively. For simplifying the computing, we did not construct the glass substrate with a thickness of 1.1 mm. But we set the bottom boundary of ITO layer as the rigid boundary, considering the restriction of the thick glass substrate. After setting the boundary conditions for temperature, the temperature distribution was first calculated. The temperature values were then used as initial values for subsequent simulations of thermal stress and elastic deformation.

The disclosed experimental data was designed to establish the feasibility and reproducibility of the claimed process under representative conditions. The chosen materials and process parameters reflect the desired outcomes and are aligned with standard practices in the field. The focus of the current disclosure was to demonstrate the viability of the process under the specific conditions described. While the experimental data provided focuses on specific conditions, the process is not intended to be limited to these embodiments. The methodology described herein is adaptable to a range of conditions, and variations in the components could be explored to optimize the process for specific applications. The selection of the described parameters was based on their practical relevance and alignment with the objectives of this invention.

What is claimed is:

1. A perovskite layer comprising a perovskite compound and a surfactant, wherein the perovskite compound is represented by Formula 1: 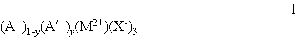
wherein y is 0.01-0.99;
M²⁺ is Pb²⁺, Sn²⁺, or Ge²⁺;
each of A⁺ and A′⁺ is independently Cs⁺, Rb⁺, CH₃NH₃⁺, CH₃CH₂NH₃⁺, H(C═NH₂)NH₂⁺, or Me(C═NH₂)NH₂⁺; and
X⁻ for each instance is independently F⁻, Cl⁻, Br⁻, or I⁻, wherein A⁺ and A′⁺ are the same or different; and
the surfactant comprises a sulfonate surfactant, an alcohol alkoxylate surfactant, a quaternary ammonium surfactant, or mixtures thereof.

2. The perovskite layer of claim 1, wherein the sulfonate surfactant comprises a sulfonic group substituted by a halogenated C₄-C₁₂ alkyl.

3. The perovskite layer of claim 1, wherein the quaternary ammonium surfactant comprises one or more C₁-C₁₆ alkyl substituents.

4. The perovskite layer of claim 1, wherein the surfactant comprises one or more of potassium tridecafluorohexane-1-sulfonate, sodium tridecafluorohexane-1-sulfonate, potassium nonafluorobutane-1-sulfonate, sodium nonafluorobutane-1-sulfonate, potassium henicosafluorodecane-1-sulfonate, sodium henicosafluorodecane-1-sulfonate, a poly(ethylene oxide)/poly(propylene oxide) (EO/PO) block copolymer, or N,N,N-trimethyloctan-1-aminium chloride.

5. The perovskite layer of claim 1, wherein M²⁺ is Pb²⁺; and each of A⁺ and A′⁺ is independently Cs⁺, CH₃NH₃⁺, or H(C═NH₂)NH₂⁺.

6. The perovskite layer of claim 1, wherein the perovskite layer comprises (H(C═NH₂)NH₂⁺)_{1-y}(Cs⁺)_{y}(Pb²⁺)(I⁻)₃, wherein y is 0.01-0.99.

7. The perovskite layer of claim 1, wherein the perovskite layer comprises a perovskite of Formula 2: 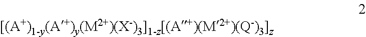
wherein y is 0.01-0.99;
z is 0.01-0.99;
M²⁺ is Pb²⁺, Sn²⁺, or Ge²⁺;
M′²⁺ is Pb²⁺, Sn²⁺, or Ge²⁺;
each of A⁺, A′⁺, and A″⁺ is independently Cs⁺, Rb⁺, CH₃NH₃⁺, CH₃CH₂NH₃⁺, H(C═NH₂)NH₂⁺, or Me(C═NH₂)NH₂⁺; and
X⁻ and Q⁻ for each instance is independently F⁻, Cl⁻, Br⁻, or I⁻, wherein A⁺ and A′⁺ are the same or different.

8. The perovskite layer of claim 7, wherein each of M²⁺ and M′²⁺ is Pb²⁺; each of A⁺ and A′⁺ is independently Cs⁺, CH₃NH₃⁺, or H(C═NH₂)NH₂⁺; and A″⁺ is CH₃NH₃⁺.

9. The perovskite layer of claim 7, wherein the perovskite layer comprises [(H(C═NH₂)NH₂⁺)_{1-y}(Cs⁺)_{y}(Pb²⁺)(I⁻)₃]_{1-z}[(CH₃NH₃⁺)(Pb²⁺)(Br)₃]_{z}, wherein y is 0.01-0.99 and z is 0.01-0.99.

10. The perovskite layer of claim 1, wherein the perovskite layer comprises a plurality of perovskite grains, and a bottom surface of each of the plurality of perovskite grains comprises a single grain surface concave (GSC) and a convex ridge around the GSC, and wherein the average angle of the perovskite grains between the line connecting the apex of the convex ridge to the center of the GSC and a top surface opposite to the bottom surface of the grain is 0°-1.5°.

11. The perovskite layer of claim 1, wherein the perovskite layer comprises a plurality of perovskite grains and a grain-boundary grooving (GBG) between the bottom surfaces of each of the adjacent perovskite grains, the GBG is surrounded by edges of the adjacent perovskite grains as a GBG sidewall, and wherein the average angle θ of the perovskite grains between the tangent to the GBG sidewall and a top surface opposite to the bottom surface of the grain is 0°-15°.

12. A method for producing the perovskite layer according to claim 1, wherein the method comprises:
providing a perovskite precursor solution comprising one or more metal salts each independently represented by the formula MX₂, two or more salts each independently represented by the formula AZ, the surfactant, and a solvent, wherein M is Pb²⁺, Sn²⁺, or Ge²⁺, A is Cs⁺, Rb⁺, CH₃NH₃⁺, CH₃CH₂NH₃⁺, H(C═NH₂)NH₂⁺, or Me(C═NH₂)NH₂⁺, X for each instance is independently F⁻, Cl⁻, Br⁻, or I⁻, and Z for each instance is independently F⁻, Cl⁻, Br⁻, or I⁻;
depositing the perovskite precursor solution on a surface of a charge transport layer to form a wet film; and
annealing the wet film to form the perovskite layer.

13. The method of claim 12, wherein the perovskite precursor solution comprises (Cs⁺)(I⁻), (H(C═NH₂)NH₂⁺)(I⁻), (Pb²⁺)(I⁻)₂, and tridecafluorohexane-1-sulfonate.

14. The method of claim 12, wherein the perovskite precursor solution comprises (Cs⁺)(I⁻), (H(C═NH₂)NH₂⁺)(I⁻), (CH₃NH₃⁺)(Cl⁻), (Pb²⁺)( )₂, (CH₃NH₃⁺)(Pb²⁺)(Br⁻)₃, and tridecafluorohexane-1-sulfonate.

15. The method according to claim 12, wherein the surfactant has a concentration of 0.1-5 mg/ml in the perovskite precursor solution.

16. The method according to claim 12, wherein the one or more metal salts have a concentration of 0.5-2.0 M in the perovskite precursor solution.

17. A photoelectric device comprising the perovskite layer according to claim 1.

18. The photoelectric device according to claim 17, wherein the photoelectric device is a perovskite solar cell (PSC), a perovskite light-emitting diode, a perovskite laser, or a perovskite photodetector.

19. The photoelectric device according to claim 18, wherein the perovskite solar cell comprises an interfacial glue layer between the perovskite compound film and an adjacent charge transport layer.

20. The photoelectric device according to claim 18, wherein the photoelectric conversion efficiency of the perovskite solar cell is 23.5-25.5%.
